(19) United States
(12) Patent Application Publication
(10) Pub. No.: US 2026/0098106 A1
(43) Pub. Date: Apr. 9, 2026

(54) POLYMER, RESIST COMPOSITION INCLUDING THE SAME, AND PATTERN FORMATION METHOD USING THE RESIST COMPOSITION

(71) Applicant: Samsung Electronics Co., Ltd., Suwon-si (KR)

(72) Inventors: Minsang Kim, Suwon-si (KR); Cheol Kang, Suwon-si (KR); Beomseok Kim, Suwon-si (KR); Hyeran Kim, Suwon-si (KR); Sungan Do, Suwon-si (KR); Yonghoon Moon, Suwon-si (KR); Hoyoon Park, Suwon-si (KR); Chanjae Ahn, Suwon-si (KR); Aram Jeon, Suwon-si (KR); Sungwon Choi, Suwon-si (KR)

(73) Assignee: Samsung Electronics Co., Ltd., Suwon-si (KR)

(21) Appl. No.: 19/328,930

(22) Filed: Sep. 15, 2025

(30) Foreign Application Priority Data
Oct. 7, 2024 (KR) 10-2024-0135966

(51) Int. Cl. C08F 8/02; C08F 212/14; C08F 220/18; G03F 7/004; G03F 7/039; G03F 7/20; G03F 7/32

(52) U.S. Cl. CPC C08F 8/02; C08F 212/24; C08F 220/1807; G03F 7/0045; G03F 7/039; G03F 7/20; G03F 7/322

(57) ABSTRACT

Provided are a polymer, a resist composition including the same, and a pattern formation method using the resist composition, the polymer including a first chain including a first repeating unit represented by Formula 1, a second chain including a second repeating unit represented by Formula 2, and a crosslinking unit represented by Formula 9 linking the first chain and the second chain:

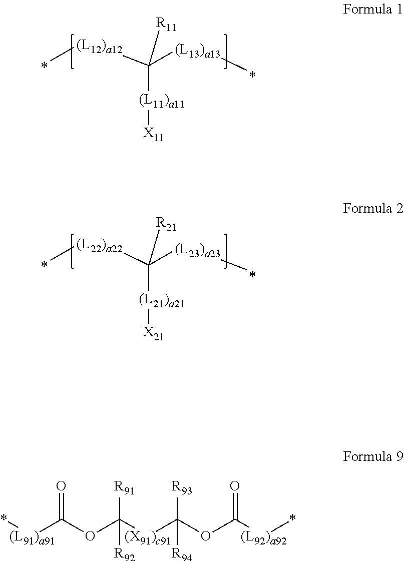

The descriptions of L₁₁ to L₁₃, L₂₁ to L₂₃, a11 to a13, a21 to a23, R₁₁, R₂₁, X₁₁, X₂₁, L₉₁, L₉₂, a91, a92, R₉₁ to R₉₄, X₉₁, and c91 in Formulae 1, 2 and 9 are provided herein.

### CROSS-REFERENCE TO RELATED APPLICATION

This application is based on and claims priority under 35 U.S.C. § 119 to Korean Patent Application No. 10-2024-0135966, filed on Oct. 7, 2024, in the Korean Intellectual Property Office, the disclosure of which is incorporated by reference herein in its entirety.

### BACKGROUND

### 1. Field

The disclosure relates to a polymer, a resist composition including the same, and/or a pattern formation method using the resist composition.

### 2. Description of the Related Art

During manufacturing a semiconductor device, resists may have physical properties that change in response to light and may be used to form fine patterns. Among the resists, chemically amplified resists may be used. A chemically amplified resist enables patterning by allowing acids, formed by a reaction between light and photoacid generators, to react again with a base resin, changing the solubility of the base resin in a developer.

In particular, when using high-energy rays with relatively high energy, such as extreme ultraviolet (EUV), the number of photons may be significantly smaller than when irradiating light of the same energy. Accordingly, there may be a need for resist compositions that may be effective when used in small amounts, and that may provide improved sensitivity, improved resolution, and/or reduced defects.

### SUMMARY

Provided are a polymer capable of providing improved sensitivity and/or resolution, a resist composition including the same, and a pattern formation method using the resist composition.

Additional aspects will be set forth in part in the description which follows and, in part, will be apparent from the description, or may be learned by practice of the presented embodiments of the disclosure.

According to an embodiment of the disclosure, a polymer may include a first chain including a first repeating unit represented by Formula 1, a second chain including a second repeating unit represented by Formula 2, and a crosslinking unit represented by Formula 9, the crosslinking unit linking the first chain and the second chain:

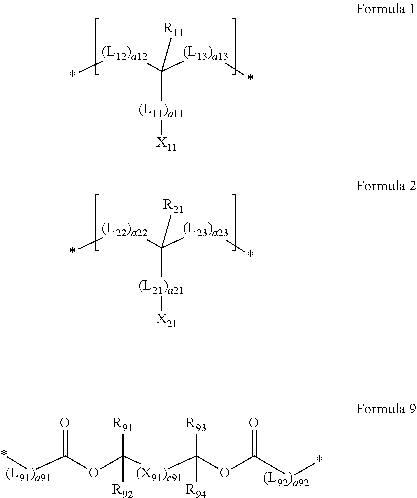

wherein, in Formulae 1, 2, and 9,
L₁₁ to L₁₃ may each independently be a single bond, O, S, C(═O), C(═O)O, OC(═O), C(═O)NR₁₂, NR₁₂C(═O), S(═O), S(═O)₂O OS(═O)₂, or a linear, branched, or cyclic C₁-C₃₀ divalent hydrocarbon group optionally including a heteroatom,
L₂₁ to L₂₃ may each independently be a single bond, O, S, C(═O), C(═O)O, OC(═O), C(═O)NR₂₂, NR₂₂C(═O), S(═O), S(═O)₂O, OS(═O)₂, or a linear, branched, or cyclic C₁-C₃₀ divalent hydrocarbon group optionally including a heteroatom,
a11 to a13 and a21 to a23 may each independently be an integer from 1 to 4,
R₁₁, R₁₂, R₂₁, and R₂₂ may each independently be hydrogen, deuterium, a halogen atom, a cyano group, a hydroxyl group, an amino group, a carboxylate group, a thiol group, an ester moiety, a sulfonate moiety, a carbonate moiety, a lactone moiety, a sultone moiety, a carboxylic anhydride moiety, or a linear, branched, or cyclic C₁-C₃₀ monovalent hydrocarbon group optionally including a heteroatom,
X₁₁ and X₂₁ may each independently be an acid labile group,
L₁₁ and L₉₂ may each independently be a single bond, or a linear, branched, or cyclic C₁-C₃₀ divalent hydrocarbon group optionally including a heteroatom,
a91 and a92 may each independently be an integer from 1 to 4,
R₉₁ to R₉₄ may each independently be a linear, branched, or cyclic C₁-C₃₀ monovalent hydrocarbon group optionally including a heteroatom, and R₉₁ and R₉₂ or R₉₃ and R₉₄ may optionally be bonded to each other to form a ring,
X₉₁ may be a linear, branched, or cyclic C₁-C₃₀ divalent hydrocarbon group optionally including a heteroatom,
c91 may be an integer from 1 to 4, and
* indicates a binding site to a neighboring atom.

According to an embodiment of the disclosure, a resist composition may include the above-described polymer, a photoacid generator, and a solvent.

According to an embodiment of the disclosure, a pattern formation method may include applying the above-described resist composition to form a resist film, exposing at least a portion of the resist film to a high-energy ray to provide an exposed resist film, and developing the exposed resist film using a developer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart illustrating a pattern formation method according to an embodiment;

FIGS. 2A to 2C are side cross-sectional views illustrating a pattern formation method according to an embodiment;

FIGS. 3A to 3E are side cross-sectional views illustrating a method of forming a patterned structure according to an embodiment;

FIGS. 4A to 4E are side cross-sectional views illustrating a method of forming a semiconductor device according to an embodiment;

FIG. 5A is a diagram illustrating the change in film thickness after development according to a deep ultraviolet (DUV) dose of Polymers HS/ECPMA, E-HS/ECPMA2, and E-HS/ECPMA4, and FIG. 5B is a diagram illustrating the change in film thickness after development according to an extreme ultraviolet (EUV) dose of Polymers HS/ECPMA, E-HS/ECPMA2, and E-HS/ECPMA4; and

FIG. 6 is a diagram illustrating the results of gel permeation chromatography analysis after exposure of Polymers HS/ECPMA and E-HS/ECPMA2.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC. When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Because the disclosure may have diverse modified embodiments, embodiments are illustrated in the drawings and are described in the detailed description. However, it should be understood that this is not intended to limit the disclosure to specific embodiments, and includes all modifications, equivalents, and substitutes included in the spirit and scope of the disclosure. In describing the disclosure, when it is determined that the specific description of the known related art obscures the gist of the disclosure, the detailed description thereof will be omitted.

It will be understood that, although the terms “first,” “second,” and “third” may be used herein to describe various elements, these elements should not be limited by these terms. These terms are only used to distinguish one element from another element and not used to limit order or types of elements.

In the present specification, when a portion of a layer, film, region, plate, or the like is described as being “on” or “above” another portion, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Hereinafter, unless explicitly described to the contrary, it is to be understood that the terms such as “including” or “having” are intended to indicate the existence of the features, numbers, steps, operations, components, parts, ingredients, materials, or combinations thereof disclosed in the specification and are not intended to preclude the possibility that one or more other features, numbers, steps, operations, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

The expression “Cr-Cy” used herein refers to the case where the number of carbon atoms constituting a substituent is in a range of x to y. For example, the expression “C₁-C₆” refers to the case where the number of carbon atoms constituting a substituent is in a range of 1 to 6, and the expression “C₆-C₂₀” refers to the case where the number of carbon atoms constituting a substituent is in a range of 6 to 20.

The term “monovalent hydrocarbon group” used herein refers to a monovalent residue derived from an organic compound including carbon and hydrogen or a derivative thereof, and specific examples thereof may include: a linear or branched alkyl group (e.g., a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); a monovalent saturated cycloaliphatic hydrocarbon group (a cycloalkyl group) (e.g., a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group); a monovalent unsaturated aliphatic hydrocarbon group (an alkenyl group or an alkynyl group) (e.g., an allyl group); a monovalent unsaturated cycloaliphatic hydrocarbon group (a cycloalkenyl group) (e.g., 3-cyclohexenyl); an aryl group (e.g., a phenyl group, a 1-naphthyl group, and a 2-naphthyl group); an arylalkyl group (e.g., a benzyl group and a diphenylmethyl group); a heteroatom-containing monovalent hydrocarbon group (e.g., a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group), or any combination thereof. In addition, in these groups, some hydrogen atoms may be substituted by a moiety including a heteroatom such as oxygen, sulfur, nitrogen, phosphorus, or halogen, or some carbon atoms may be substituted by a moiety including a heteroatom such as oxygen, sulfur, nitrogen, or phosphorus, so that these groups may include a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, and the like.

The term “divalent hydrocarbon group” as used herein is a divalent residue and means that any one hydrogen atom of the monovalent hydrocarbon group is replaced with a binding site to a neighboring atom. The divalent hydrocarbon group may include, for example, a linear or branched alkylene group, a cycloalkylene group, an alkenylene group, an alkynylene group, a cycloalkylene group, an arylene group, a group in which some carbon atoms thereof are replaced with a heteroatom, and the like.

The term “alkyl group” as used herein refers to a linear or branched saturated aliphatic hydrocarbon monovalent group, and specific examples thereof may include a methyl group, an ethyl group, a propyl group, an isobutyl group, a sec-butyl group, a tert-butyl group, a pentyl group, an iso-amyl group, a hexyl group, and the like. The term “alkylene group” as used herein refers to a linear or branched saturated aliphatic hydrocarbon divalent group, and specific examples thereof may include a methylene group, an ethylene group, a propylene group, a butylene group, an isobutylene group, and the like.

The term “halogenated alkyl group” as used herein refers to a group in which one or more substituents of an alkyl group are substituted with halogen, and specific examples thereof may include CF₃ and the like. Wherein, halogen may be F, Cl, Br, or I.

The term “alkoxy group” as used herein refers to a monovalent group having a Formula of -OA₁₀₁, wherein A₁₀₁ may be an alkyl group. Specific examples thereof may include a methoxy group, an ethoxy group, an isopropyloxy group, and the like.

The term “alkylthio group” as used herein refers to a monovalent group having a Formula of -SA₁₀₁, wherein A₁₀₁ may be an alkyl group.

The term “halogenated alkoxy group” as used herein refers to a group in which one or more hydrogen atoms of an alkoxy group are substituted with halogen, and specific examples thereof may include —OCF₃ and the like.

The term “halogenated alkylthio group” as used herein refers to a group in which one or more hydrogen atoms of an alkylthio group are substituted with halogen, and specific examples thereof may include —SCF₃ and the like.

The term “cycloalkyl group” as used herein refers to a monovalent saturated hydrocarbon cyclic group, and specific examples thereof may include monocyclic groups such as a cyclopropyl group, a cyclobutyl group, a cyclopentyl group, a cyclohexyl group, and a cycloheptyl group, and polycyclic condensed cyclic groups such as a norbornyl group and an adamantyl group. The term “cycloalkylene group” as used herein refers to a divalent saturated hydrocarbon cyclic group, and specific examples thereof may include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and the like.

The term “cycloalkoxy group” as used herein refers to a monovalent group having a Formula of -OA₁₀₂, wherein A₁₀₂ may be a cycloalkyl group. Specific examples thereof may include a cyclopropoxy group, a cyclobutoxy group, and the like.

The term “cycloalkylthio group” as used herein refers to a monovalent group having a Formula of -SA₁₀₂, wherein A₁₀₂ may be a cycloalkyl group.

The term “heterocycloalkyl group” as used herein may be a group in which some carbon atoms of the cycloalkyl group are replaced by a moiety including a heteroatom, such as oxygen, sulfur, or nitrogen. The heterocycloalkyl group may include an ether bond, an ester bond, a sulfonate bond, carbonate, a lactone ring, a sultone ring, or a carboxylic anhydride moiety. The term “heterocycloalkylene group” as used herein refers to a group in which some carbon atoms of the cycloalkylene group are replaced by a moiety including a heteroatom, such as oxygen, sulfur, or nitrogen.

The term “heterocycloalkoxy group” as used herein refers to a monovalent group having a Formula of -OA₁₀₃, wherein A₁₀₃ may be a heterocycloalkyl group.

The term“heterocycloalkylthio group” as used herein refers to a monovalent group having a Formula of -SA₁₀₃, where A₁₀₃ may be a heterocycloalkyl group.

The term “alkenyl group” as used herein refers to a linear or branched unsaturated aliphatic hydrocarbon monovalent group including one or more carbon-carbon double bonds. The term “alkenylene group” as used herein refers to a linear or branched unsaturated aliphatic hydrocarbon divalent group including one or more carbon-carbon double bonds.

The term “cycloalkenyl group” as used herein refers to a monovalent unsaturated hydrocarbon cyclic group including one or more carbon-carbon double bonds. The term “cycloalkenylene group” as used herein refers to a divalent unsaturated hydrocarbon cyclic group including one or more carbon-carbon double bonds.

The term “heterocycloalkenyl group” as used herein refers to a group in which some carbon atoms of the cycloalkenylene group are replaced by a moiety including a heteroatom, such as oxygen, sulfur, or nitrogen. The term “heterocycloalkenylene group” as used herein refers to a group in which some carbon atoms of the cycloalkenylene group are replaced by a moiety including a heteroatom, such as oxygen, sulfur, or nitrogen.

The term “alkynyl group” as used herein refers to a linear or branched unsaturated aliphatic hydrocarbon monovalent group including one or more carbon-carbon triple bonds.

The term “aryl group” as used herein refers to a monovalent group having a carbocyclic aromatic system, and specific examples thereof may include a phenyl group, a naphthyl group, an anthracenyl group, a phenanthrenyl group, a pyrenyl group, a chrysenyl group, and the like. The term “arylene group” as used herein refers to a divalent group having a carbocyclic aromatic system.

The term “aryloxy group” as used herein refers to a monovalent group having a Formula of -OA₁₀₄, wherein A₁₀₄ may be an aryl group.

The term “arylthio group” as used herein refers to a monovalent group having a Formula of -SA₁₀₄, where A₁₀₄ may be an aryl group.

The term “heteroaryl group” as used herein refers to a monovalent group having a heterocyclic aromatic system, and specific examples thereof may include a pyridinyl group, a pyrimidinyl group, a pyrazinyl group, and the like. The term “heteroarylene group” as used herein refers to a divalent group having a heterocyclic aromatic system.

The term “heteroaryloxy group” as used herein refers to a monovalent group having a Formula of -OA₁₀₅, wherein A₁₀₅ may be a heteroaryl group.

The term “heteroarylthio group” as used herein refers to a monovalent group having a Formula of -SA₁₀₅, wherein A₁₀₅ may be a heteroaryl group.

The term “arylalkyl group” as used herein refers to a group in which a monovalent group having a carbocyclic aromatic system is substituted on an alkyl group, and specific examples thereof may include a benzyl group, a diphenylmethyl group, and the like.

The term “heteroarylalkyl group” as used herein refers to a group in which a monovalent group having a heterocyclic aromatic system is substituted on an alkyl group.

The term “heterocyclic group” refers to a monocyclic or polycyclic group having 1 to 60 carbon atoms and including at least one heteroatom, and is a group including a monovalent group, a divalent group, a trivalent group, and the like.

The term “substituent” as used herein may include: deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group;
a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group, each substituted with deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, or any combination thereof; or any combination thereof.

Hereinafter, embodiments will be described in detail with reference to the accompanying drawings, wherein like reference numerals denote substantially the same or corresponding components throughout the drawings, and a redundant description thereof will be omitted. In the drawings, thicknesses are enlarged to clearly represent various layers and regions. Also, in the drawings, thicknesses of some layers and regions are exaggerated for convenience of description. Meanwhile, embodiments set forth herein are merely examples and various changes may be made therein.

### [Polymer]

According to an embodiment, a polymer may include: a first chain including a first repeating unit represented by Formula 1; a second chain including a second repeating unit represented by Formula 2; and a crosslinking unit represented by Formula 9 linking the first chain and the second chain:

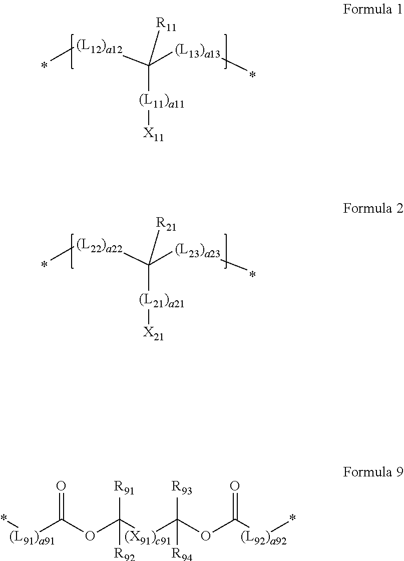

wherein, in Formulae 1, 2, and 9,
L₁₁ to L₁₃ may each independently be: a single bond; O; S; C(═O); C(═O)O; OC(═O); C(═O)NR₁₂; NR₁₂C(═O); S(═O); S(═O)₂O; OS(═O)₂; or a linear, branched, or cyclic C₁-C₃₀ divalent hydrocarbon group optionally including a heteroatom,
L₂₁ to L₂₃ may each independently be: a single bond; O; S; C(═O); C(═O)O; OC(═O); C(═O)NR₂₂; NR₂₂C(═O); S(═O); S(═O)₂O; OS(═O)₂; or a linear, branched, or cyclic C₁-C₃₀ divalent hydrocarbon group optionally including a heteroatom,
a11 to a13 and a21 to a23 may each independently be an integer from 1 to 4,
R₁₁, R₁₂, R₂₁, and R₂₂ may each independently be: hydrogen; deuterium; a halogen atom; a cyano group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched, or cyclic C₁-C₃₀ monovalent hydrocarbon group optionally including a heteroatom,
X₁₁ and X₂₁ may each independently be an acid labile group,
L₉₁ and L₉₂ may each independently be: a single bond; or a linear, branched, or cyclic C₁-C₃₀ divalent hydrocarbon group optionally including a heteroatom,
a91 and a92 may each independently be an integer from 1 to 4,
R₉₁ to R₉₄ may each independently be a linear, branched, or cyclic C₁-C₃₀ monovalent hydrocarbon group optionally including a heteroatom, and R₉₁ and R₉₂ or R₉₃ and R₉₄ may optionally be bonded to each other to form a ring,
X₉₁ may be a linear, branched, or cyclic C₁-C₃₀ divalent hydrocarbon group optionally including a heteroatom,
c91 may be an integer from 1 to 4, and
* indicates a binding site to a neighboring atom.

For example, in Formulae 1 and 2, L₁₁ to L₁₃ and L₂₁ to L₂₃ may each independently be: a single bond; O; S; C(═O); C(═O)O; OC(═O); C(═O)NH; NHC(═O); S(═O); S(═O)₂; S(═O)₂O; OS(═O)₂; a substituted or unsubstituted C₁-C₃₀ alkylene group; a substituted or unsubstituted C₃-C₃₀ cycloalkylene group; a substituted or unsubstituted C₃-C₃₀ heterocycloalkylene group; a substituted or unsubstituted C₂-C₃₀ alkenylene group; a substituted or unsubstituted C₃-C₃₀ cycloalkenylene group; a substituted or unsubstituted C₃-C₃₀ heterocycloalkenylene group; a substituted or unsubstituted C₆-C₃₀ arylene group; or a substituted or unsubstituted C₁-C₃₀ heteroarylene group.

Specifically, in Formulae 1 and 2, L₁₁ to L₁₃ and L₂₁ to L₂₃ may each independently be selected from: a single bond; O; C(═O); C(═O)O; OC(═O); C(═O)NH; NHC(═O); and a C₁-C₂₀ alkylene group, a C₃-C₂₀ cycloalkylene group, a C₃-C₂₀ heterocycloalkylene group, a C₂-C₂₀ alkenylene group, a C₃-C₂₀ cycloalkenylene group, a C₃-C₂₀ heterocycloalkenylene group, a C₆-C₂₀ arylene group, and a C₁-C₂₀ heteroarylene group, each unsubstituted or substituted with deuterium, a halogen atom, a cyano group, a hydroxyl group, an amino group, a carboxylate group, a thiol group, an ester moiety, a sulfonate moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

More specifically, in Formulae 1 and 2, L₁₁ to L₁₃ and L₂₁ to L₂₃ may each independently be selected from: a single bond; O; C(═O); C(═O)O; OC(═O); C(═O)NH; NHC(═O); and a C₁-C₂₀ alkylene group, a C₃-C₂₀ cycloalkylene group, a C₃-C₂₀ heterocycloalkylene group, a phenylene group, and a naphthylene group, each unsubstituted or substituted with deuterium, a halogen, a C₁-C₂₀ alkyl group, a C₁-C₂₀ halogenated alkyl group, a C₁-C₂₀ alkoxy group, a phenyl group, a naphthyl group, or any combination thereof.

In Formula 1, a11 to a13 denote the number of repetitions of L₁₁ to L₁₃, respectively.

In Formula 2, a21 to a23 denote the number of repetitions of L₂₁ to L₂₃, respectively.

For example, in Formulae 1 and 2, all to a13 and a21 to a23 may each independently be an integer from 1 to 3.

Specifically, in Formulae 1 and 2, all to a13 and a21 to a23 may each independently be 1.

For example, In Formulae 1 and 2, R₁₁ and R₂₁ may each independently be selected from: hydrogen; deuterium; a halogen atom; a cyano group; a hydroxyl group; an amino group; a carboxylate group; a thiol group; and a C₁-C₂₀ alkyl group, a C₃-C₂₀ cycloalkyl group, and a C₆-C₂₀ aryl group, each unsubstituted or substituted with deuterium, a halogen atom, a cyano group, a hydroxyl group, an amino group, a carboxylate group, a thiol group, an ester moiety, a sulfonate moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

Specifically, In Formulae 1 and 2, R₁₁ and R₂₁ may each independently be selected from: hydrogen; deuterium; a halogen atom; a cyano group; and a C₁-C₂₀ alkyl group which is unsubstituted or substituted with deuterium, a halogen atom, a cyano group, or any combination thereof.

More specifically, in Formulae 1 and 2, R₁₁ and R₂₁ may each independently be H, D, F, CH₃, CH₂F, CHF₂, CF₃, CH₂CH₃, CHFCH₃, CHFCH₂F, CHFCHF₂, CHFCF₃, CF₂CH₃, CF₂CH₂F, CF₂CHF₂, CF₂CF₃, Cl, CH₂Cl, CHCl₂, CCl₃, CHClCH₃, CHClCH₂Cl, CHClCHCl₂, CHClCCl₃, CCl₂CH₃, CCl₂CH₂C₁, CCl₂CHCl₂, or CCl₂CCl₃.

For example, in Formulae 1 and 2, R₁₂ and R₂₂ may each independently be: hydrogen, deuterium, a halogen atom, a cyano group, a hydroxyl group, an amino group, a carboxylate group, a thiol group, a C₁-C₂₀ alkyl group, a C₁-C₂₀ halogenated alkyl group, a C₃-C₂₀ cycloalkyl group, or a C₆-C₂₀ aryl group.

In this specification, an acid labile group refers to a group which is detached from a polymer by an acid to generate a polar group, and may act to make the polymer more easily soluble in a developer, such as a tetramethylammonium hydroxide (TMAH) aqueous solution.

For example, an acid dissociation constant (pKa) of the acid labile group may be about 13 or less, specifically about 3 to about 13, and more specifically about 5 to about 10 (calculated value).

Specifically, in Formulae 1 and 2, X₁₁ and X₂₁ may each independently include a group having a tertiary acyclic alkyl carbon, a group containing a tertiary alicyclic carbon, or acetal.

More specifically, in Formulae 1 and 2, X₁₁ and X₂₁ may each independently be represented by any one of Formulae 6-1 to 6-12:

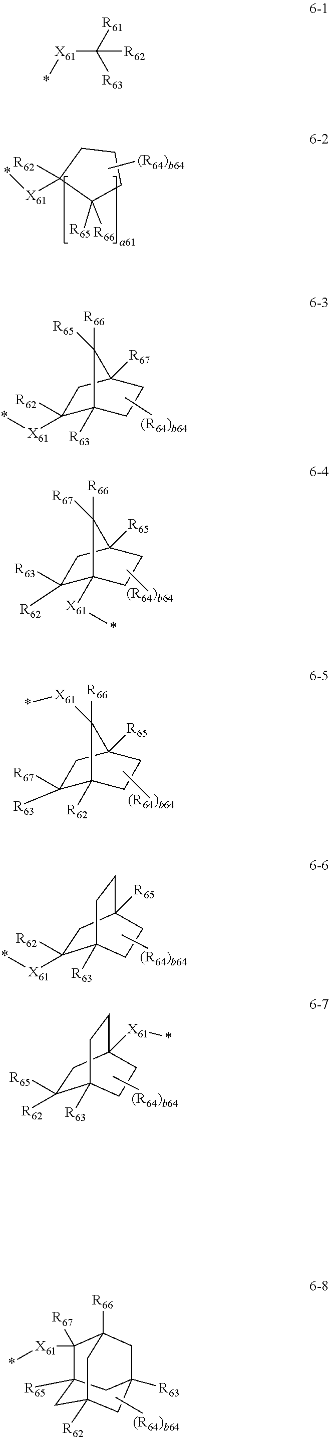

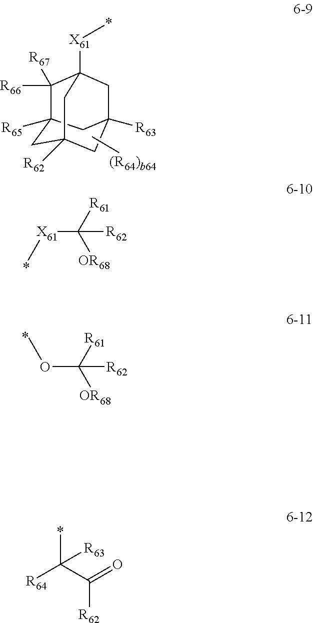

wherein, in Formulae 6-1 to 6-12,
X₆₁ may be an ester moiety, a sulfonate moiety, a carbonate moiety, or a carbamate moiety,
a61 may be an integer from 0 to 6,
R₆₁ and R₆₈ may each independently be a linear, branched, or cyclic C₁-C₂₀ monovalent hydrocarbon group optionally including a heteroatom,
R₆₂ to R₆₇ may each independently be: hydrogen; deuterium; a halogen atom; a cyano group; a hydroxyl group; an amino group; a carboxylate group; a thiol group; an ester moiety; a sulfonate moiety; a carbonate moiety; a carbamate moiety; a lactone moiety; a sultone moiety; a carboxylic anhydride moiety; or a linear, branched, or cyclic C₁-C₃₀ monovalent hydrocarbon group optionally including a heteroatom,
a neighboring two groups among R₆₁ to R₆₈ may optionally be bonded to each other to form a ring,
b64 may be an integer from 1 to 10, and
* indicates a binding site to a neighboring atom.

For example, in Formulae 6-1 to 6-12, X₆₁ may be an ester moiety or a carbonate moiety.

In particular, in Formulae 1 and 2, X₁₁ and X₂₁ may each independently be represented by any one of Formulae 6-21 to 6-46:

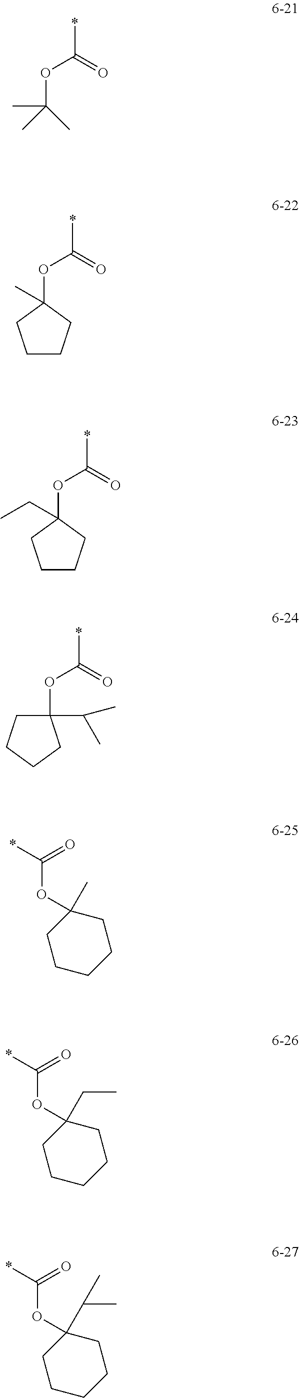

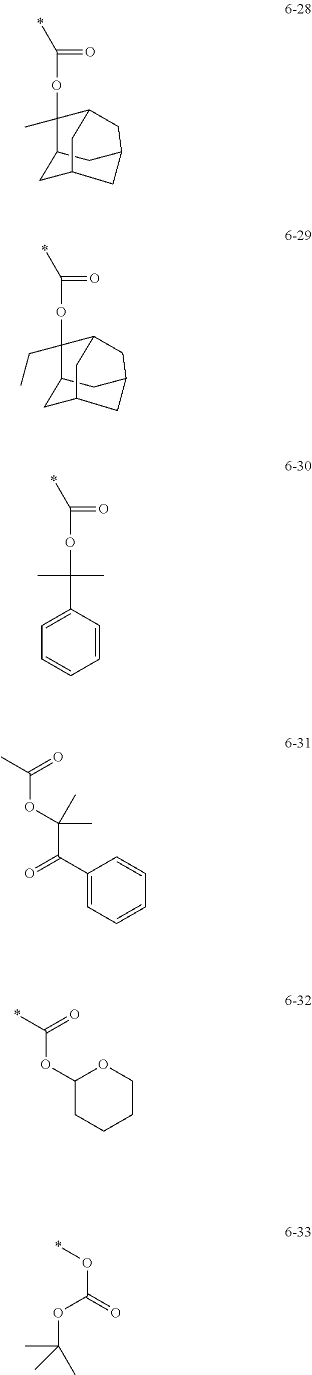

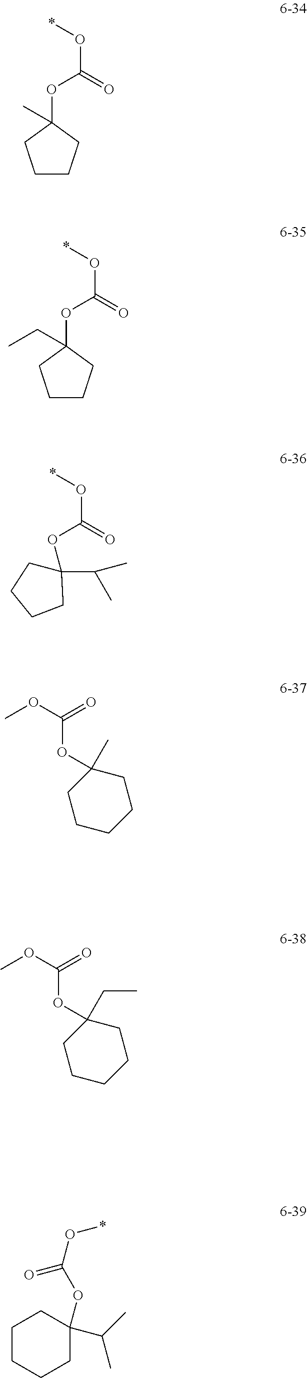

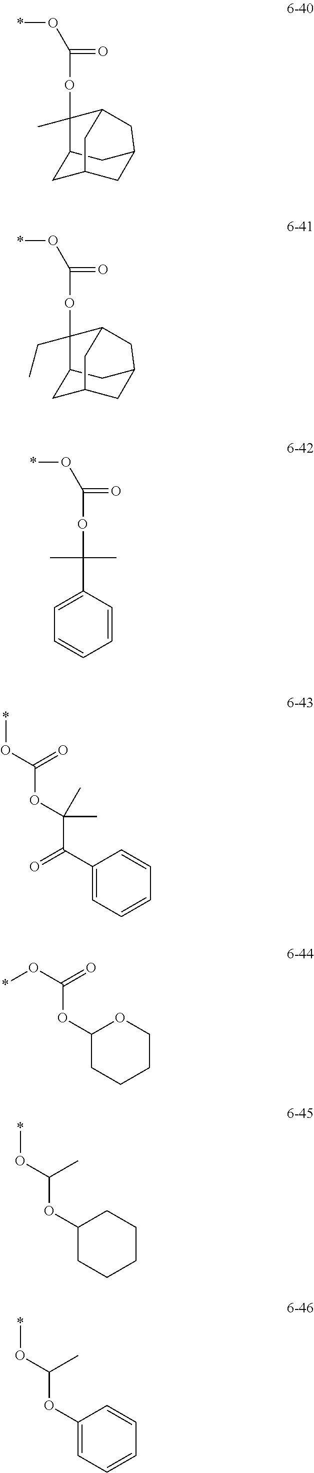

wherein, in Formulae 6-21 to 6-46,
* indicates a binding site to a neighboring atom.

In an embodiment, the first repeating unit and the second repeating unit may each independently be selected from Group I:

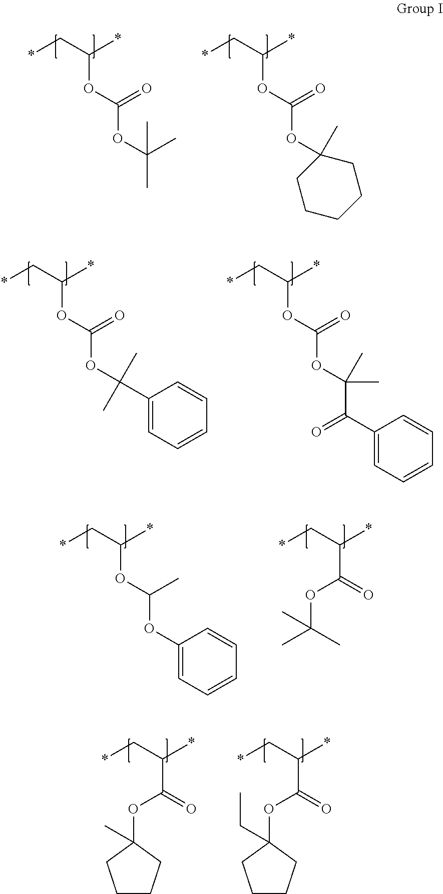

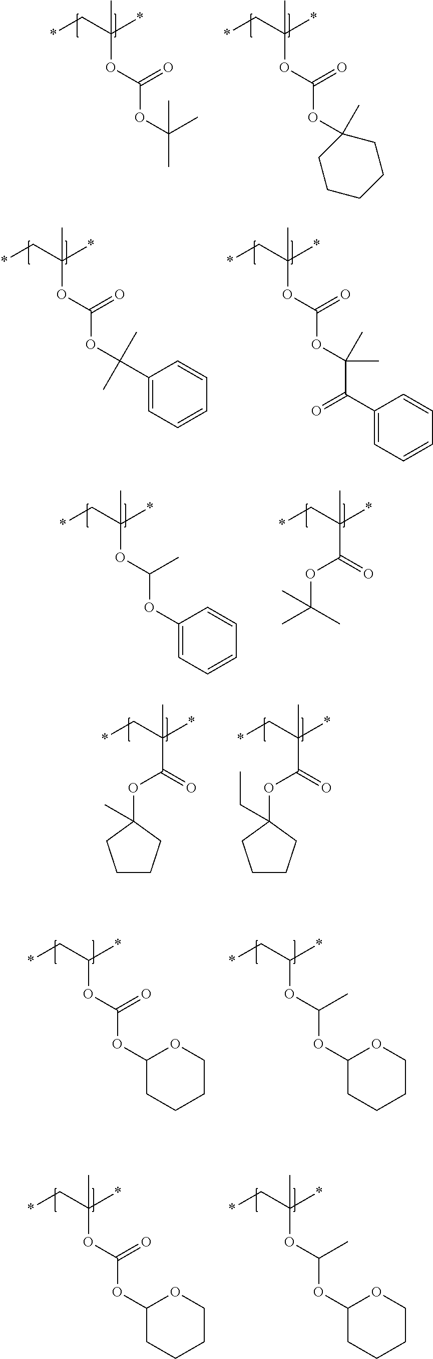

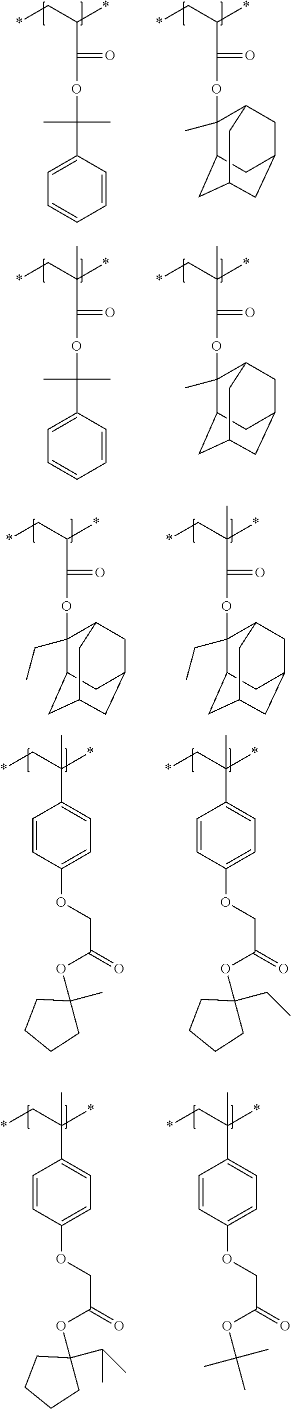

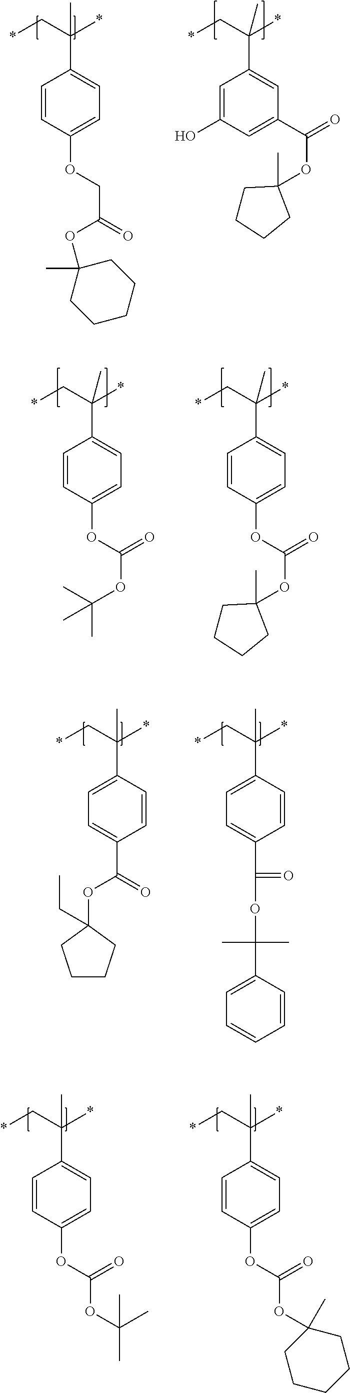

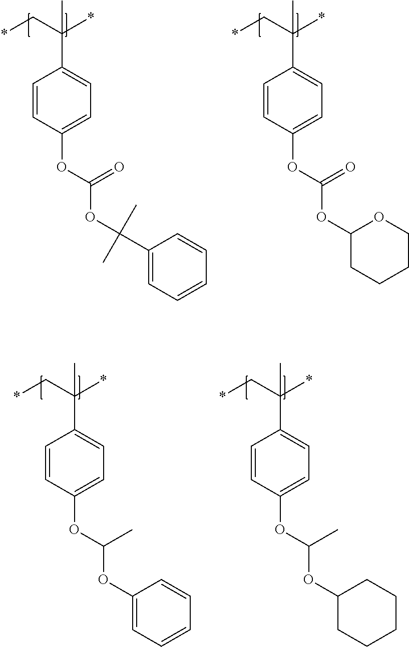

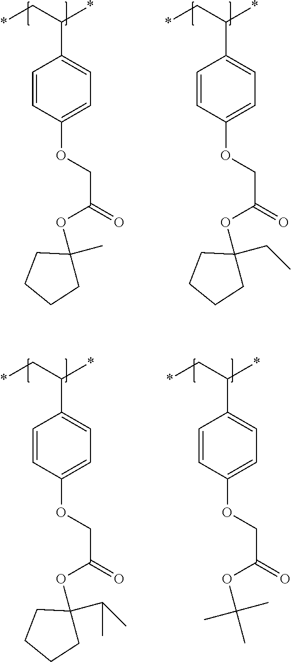

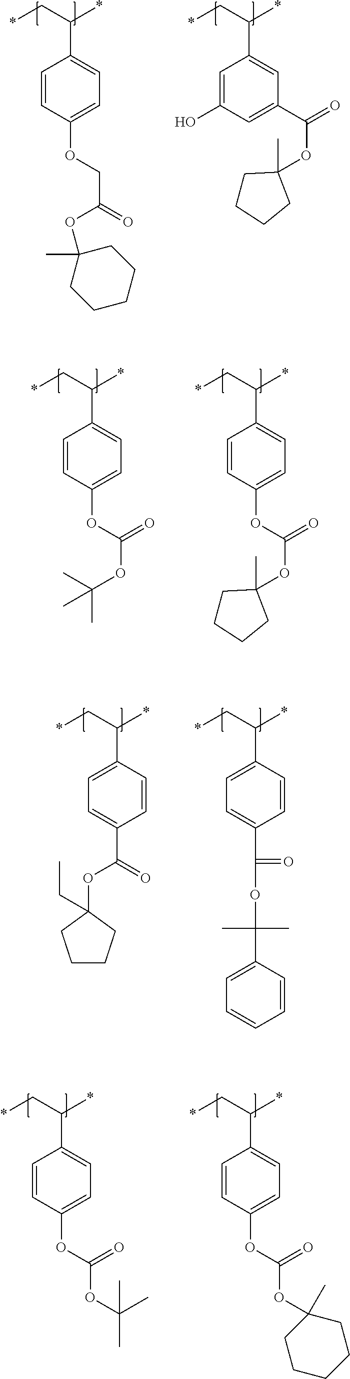

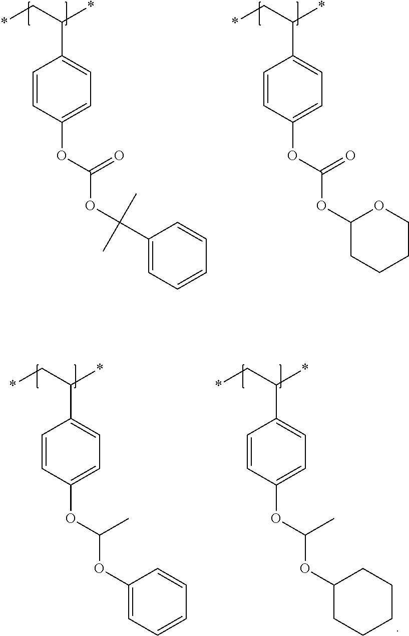

For example, in Formula 9, L₉₁ and L₉₂ may each independently be: a single bond; a substituted or unsubstituted C₁-C₃₀ alkylene group; a substituted or unsubstituted C₃-C₃₀ cycloalkylene group; a substituted or unsubstituted C₃-C₃₀ heterocycloalkylene group; a substituted or unsubstituted C₂-C₃₀ alkenylene group; a substituted or unsubstituted C₃-C₃₀ cycloalkenylene group; a substituted or unsubstituted C₃-C₃₀ heterocycloalkenylene group; a substituted or unsubstituted C₆-C₃₀ arylene group; or a substituted or unsubstituted C₁-C₃₀ heteroarylene group.

Specifically, in Formula 9, L₉₁ and L₉₂ may each independently be: a single bond; or a substituted or unsubstituted C₁-C₃₀ alkylene group.

In Formula 9, a91 and a92 denote the number of repetitions of L₉₁ and L₉₂, respectively.

For example, in Formula 9, a91 and a92 may each independently be 1.

For example, In Formula 9, R₉₁ to R₉₄ may each independently be selected from a C₁-C₂₀ alkyl group, a C₁-C₂₀ alkoxy group, a C₃-C₂₀ cycloalkyl group, a C₃-C₂₀ cycloalkoxy group, and a C₆-C₂₀ aryl group, each unsubstituted or substituted with deuterium, a hydroxyl group, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

Specifically, In Formula 9, R₉₁ to R₉₄ may each independently be a C₁-C₂₀ alkyl group which is unsubstituted or substituted with deuterium, a hydroxyl group, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

For example, in Formula 9, X₉₁ may be selected from a C₁-C₂₀ alkylene group, a C₃-C₂₀ cycloalkylene group, a C₂-C₂₀ alkenylene group, a C₃-C₂₀ cycloalkenylene group, and a C₆-C₂₀ arylene group, each unsubstituted or substituted with deuterium, a halogen, a cyano group, a nitro group, a hydroxyl group, an amino group, a carboxylate group, a thiol group, a C₁-C₂₀ alkyl group, a C₁-C₂₀ halogenated alkyl group, a C₁-C₂₀ alkoxy group, or any combination thereof.

Specifically, in Formula 9, X₉₁ may be selected from a C₃-C₂₀ cycloalkylene group and a C₆-C₂₀ arylene group, each unsubstituted or substituted with deuterium, a halogen atom, a cyano group, a nitro group, a hydroxyl group, an amino group, a carboxylate group, a thiol group, a C₁-C₂₀ alkyl group, a C₁-C₂₀ halogenated alkyl group, a C₁-C₂₀ alkoxy group, or any combination thereof.

For example, in Formula 9, c91 may be 1.

In an embodiment, the crosslinking unit may be selected from Group III:

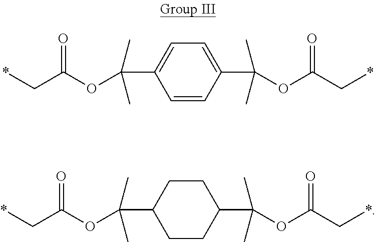

Any one hydrogen of the first chain and any one hydrogen of the second chain may be linked to * of the crosslinking unit represented by Formula 9. Specifically, any one hydrogen of X₁₁ of the first chain and any one hydrogen of X₂₁ of the second chain may be linked to * of the crosslinking unit represented by Formula 9.

In an embodiment, the polymer may include a partial structure represented by Formula 11:

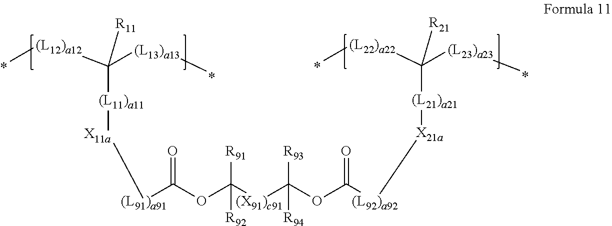

wherein, in Formula 11,
L₁₁ to L₁₃, a11 to a13, and R₁₁ may each be as in the description of Formula 1,
L₂₁ to L₂₃, a21 to a23, and R₂₁ may each be as in the description of Formula 2,
L₁₁, L₉₂, a91, a92, X₉₁, c91, and R₉₁ to R₉₄ may each be as in the description of Formula 9, and
X₁₁ₐ and X₂₁ₐ may each be a divalent acid labile group.

The crosslinking unit may include an ester bond, and thus, the polymer including the crosslinking unit may be more chemically stable than a polymer including another acid labile group, for example, an acetal bond, in a crosslinking unit. Accordingly, a resist composition including the polymer may be sufficiently stable to form a pattern.

In an embodiment, the polymer may include about 0.1 parts by weight to about 50 parts by weight, specifically about 1 parts by weight to about 40 parts by weight, and more specifically about 5 parts by weight to about 40 parts by weight of the crosslinking unit, based on 100 parts by weight of the polymer. When the amount of the crosslinking unit is within these ranges, a resist composition having improved resolution while satisfying appropriate coatability may be provided.

In an embodiment, i) the first chain may further include a third repeating unit represented by Formula 3,
ii) the second chain may further include a fourth repeating unit represented by Formula 4, or
iii) the first chain may further include a third repeating unit represented by Formula 3, and the second chain may further include a fourth repeating unit represented by Formula 4:

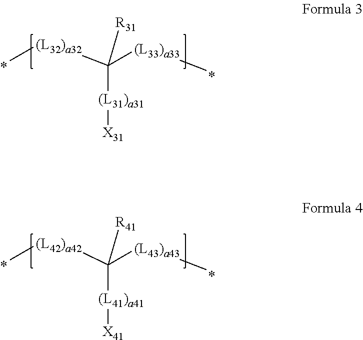

wherein, in Formulae 3 and 4,
L₃₁ to L₃₃ may each independently be: a single bond; O; S; C(═O); C(═O)O; OC(═O); C(═O)NR₃₂; NR₃₂C(═O); S(═O); S(═O)₂O; OS(═O)₂; or a linear, branched, or cyclic C₁-C₃₀ divalent hydrocarbon group optionally including a heteroatom,
L₄₁ to L₄₃ may each independently be: a single bond; O; S; C(═O); C(═O)O; OC(═O); C(═O)NR₄₂; NR₄₂C(═O); S(═O); S(═O)₂O; OS(═O)₂; or a linear, branched, or cyclic C₁-C₃₀ divalent hydrocarbon group optionally including a heteroatom,
a31 to a33 and a41 to a43 may each independently be an integer from 1 to 4,
R₃₁, R₃₂, R₄₁, and R₄₂ may each independently be: hydrogen; deuterium; a halogen atom; a cyano group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched, or cyclic C₁-C₃₀ monovalent hydrocarbon group optionally including a heteroatom,
X₃₁ and X₄₁ may each independently be a non-acid labile group, and
* indicates a binding site to a neighboring atom.

For example, when the first chain further includes the third repeating unit, any one hydrogen of the third repeating unit may be linked to * of the crosslinking unit represented by Formula 9. Specifically, any one hydrogen of X₃₁ of the first chain and any one hydrogen of X₂₁ of the second chain may be linked to * of the crosslinking unit represented by Formula 9.

For example, when the second chain further includes the fourth repeating unit, any one hydrogen of the fourth repeating unit may be linked to * of the crosslinking unit represented by Formula 9. Specifically, any one hydrogen of X₁₁ of the first chain and any one hydrogen of X₄₁ of the second chain may be linked to * of the crosslinking unit represented by Formula 9.

For example, when the first chain further includes the third repeating unit and the second chain further includes the fourth repeating unit, any one hydrogen of the third repeating unit and any one hydrogen of the fourth repeating unit may each be linked to * of the crosslinking unit represented by Formula 9. Specifically, any one hydrogen of X₃₁ of the first chain and any one hydrogen of X₄₁ of the second chain may be linked to * of the crosslinking unit represented by Formula 9.

In an embodiment, the polymer may include a partial structure represented by Formula 12:

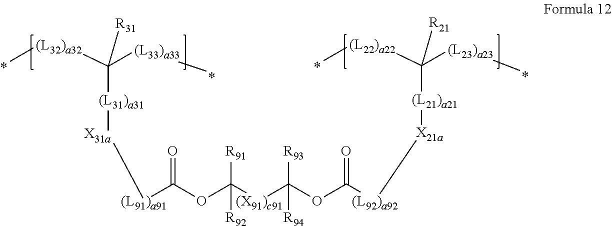

wherein, in Formula 12,
L₃₁ to L₃₃, a31 to a33, and R₃₁ may each be as in the description of Formula 3,
L₂₁ to L₂₃, a21 to a23, and R₂₁ may each be as in the description of Formula 2,
L₁₁, L₉₂, a91, a92, X₉₁, c91, and R₉₁ to R₉₄ may each be as in the description of Formula 9,
X₂₁a may be a divalent acid labile group, and X₃₁a may be a divalent non-acid labile group, and
* indicates a binding site to a neighboring atom.

In an embodiment, the polymer may include a partial structure represented by Formula 13:

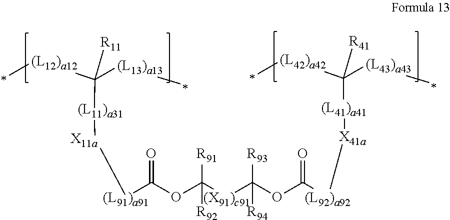

wherein, in Formula 13,
L₁₁ to L₁₃, all to a13, and R₁₁ may each be as in the description of Formula 1,
L₄₁ to L₄₃, a41 to a43, and R₄₁ may each be as in the description of Formula 4,
L₉₁, L₉₂, a91, a92, X₉₁, c91, and R₉₁ to R₉₄ may each be as in the description of Formula 9,
X₁₁ₐ may be a divalent acid labile group,
X₄₁ₐ may be a divalent non-acid labile group, and
* indicates a binding site to a neighboring atom.

In an embodiment, the polymer may include a partial structure represented by Formula 14:

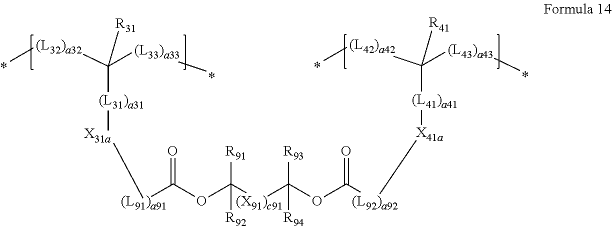

wherein, in Formula 14,
L₃₁ to L₃₃, a31 to a33, and R₃₁ may each be as in the description of Formula 3,
L₄₁ to L₄₃, a41 to a43, and R₄₁ may each be as in the description of Formula 4,
L₁₁, L₉₂, a91, a92, X₉₁, c91, and R₉₁ to R₉₄ may each be as in the description of Formula 9,
X₃₁a and X₄₁a may each be a divalent non-acid labile group, and
* indicates a binding site to a neighboring atom.

Specifically, the polymer may include a partial structure represented by Formula 14-1:

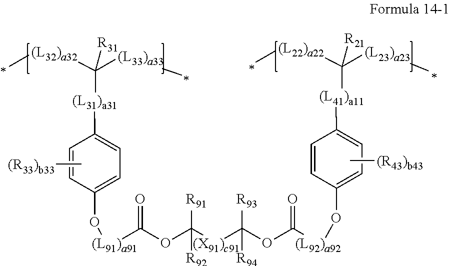

wherein, in Formula 14-1,
L₃₁ to L₃₃, a31 to a33, and R₃₁ may each be as in the description of Formula 3,
L₄₁ to L₄₃, a41 to a43, and R₄₁ may each be as in the description of Formula 4,
L₉₁, L₉₂, a91, a92, X₉₁, c91, and R₉₁ to R₉₄ may each be as in the description of Formula 9,
R₃₃ and R₄₃ may each independently be: a binding site to a neighboring atom; hydrogen; deuterium; a halogen atom; a cyano group; a hydroxyl group; an amino group; a carboxylate group; a thiol group; a carbonyl moiety; an ester moiety; a sulfonate moiety; a carbonate moiety; a carbamate moiety; a lactone moiety; a sultone moiety; a carboxylic anhydride moiety; or a linear, branched, or cyclic C₁-C₃₀ monovalent hydrocarbon group optionally including a heteroatom,
b33 and b43 may each independently be an integer from 1 to 4, and
* indicates a binding site to a neighboring atom.

In Formulae 3 and 4, L₃₁ to L₃₃ and L₄₁ to L₄₃ may be as in the description of L₁₁ of Formula 1.

In Formulae 3 and 4, a31 to a33 and a41 to a43 may be as in the description of all of Formula 1.

In Formulae 3 and 4, R₃₁ and R₄ may be as in the description of R₁₁ of Formula 1.

In Formulae 3 and 4, R₃₂ and R₄₂ may be as in the description of R₁₂ of Formula 1.

For example, In Formulae 3 and 4, X₃₁ and X₄₁ may each independently be: hydrogen; halogen; a cyano group; a hydroxyl group; a carboxylate group; a thiol group; an amino group; or a linear, branched, or cyclic C₁-C₃₀ monovalent hydrocarbon group optionally including one or more polar moieties selected from halogen, a cyano group, a hydroxyl group, a carboxylate group, a thiol group, O, C═O, C(═O)O, OC(═O), S(═O)O, OS(═O), a lactone moiety, a sultone moiety, and a carboxylic anhydride moiety.

Specifically, in Formulae 3 and 4, X₃₁ and X₄₁ may each independently be selected from hydrogen, a hydroxyl group, and groups represented by Formulae 5-1 to 5-16:

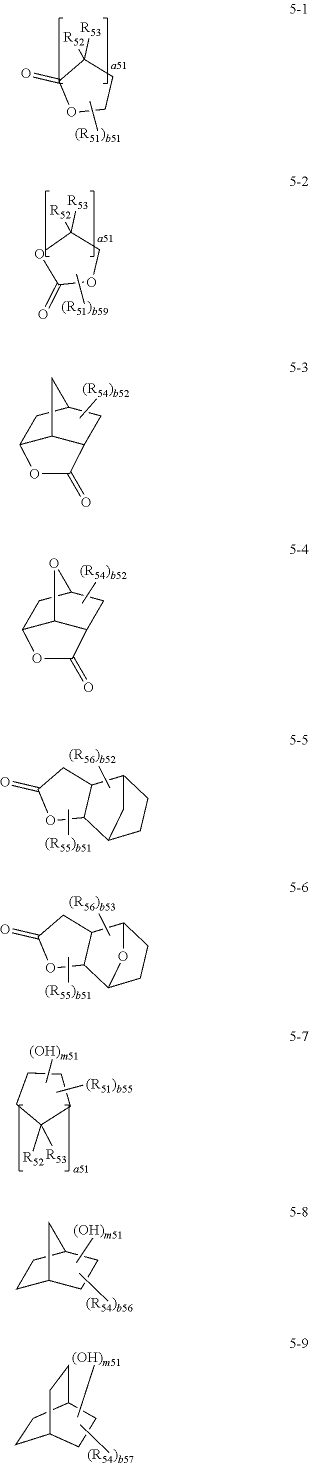

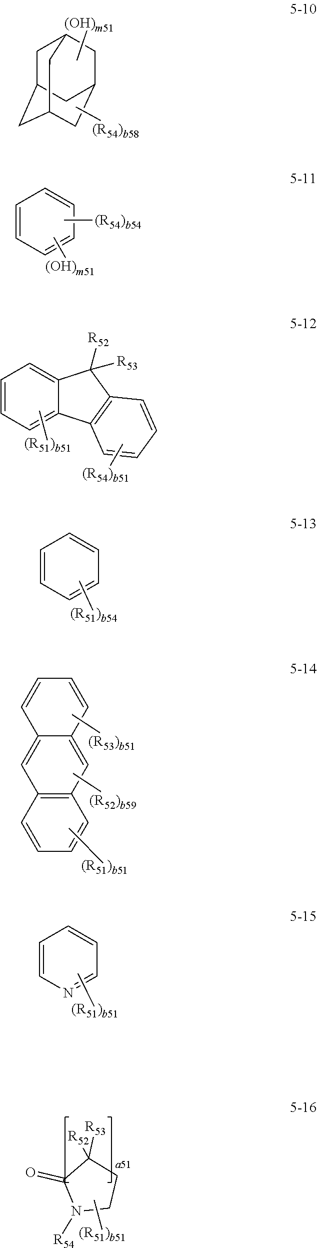

wherein, in Formulae 5-1 to 5-16,
a51 may be 1 or 2;
R₅₁ to R₅₆ may each independently be: a binding site to a neighboring atom; hydrogen; deuterium; a halogen atom; a cyano group; a hydroxyl group; an amino group; a carboxylate group; a thiol group; a carbonyl moiety; an ester moiety; a sulfonate moiety; a carbonate moiety; a carbamate moiety; a lactone moiety; a sultone moiety; a carboxylic anhydride moiety; or a linear, branched, or cyclic C₁-C₃₀ monovalent hydrocarbon group optionally including a heteroatom,
one of R₅₁ to R₅₃, one of R₅₄, and one of R₅₅ and R₅₆ may be a binding site to a neighboring atom,
b51 may be an integer from 1 to 4,
b52 may be an integer from 1 to 10,
b53 may be an integer 1 to 8,
b54 may be an integer from 1 to 5,
b55 may be an integer from 1 to 7,
b56 may be an integer from 1 to 11,
b57 may be an integer from 1 to 13,
b58 may be an integer from 1 to 15,
b59 may be an integer from 1 to 2, and
m51 may be an integer from 1 to 4.

More specifically, in Formulae 3 and 4, X₃₁ and X₄₁ may each independently be selected from a hydroxyl group and the group represented by Formulae 5-11.

In an embodiment, the third repeating unit and the fourth repeating unit may each independently be selected from Group II:

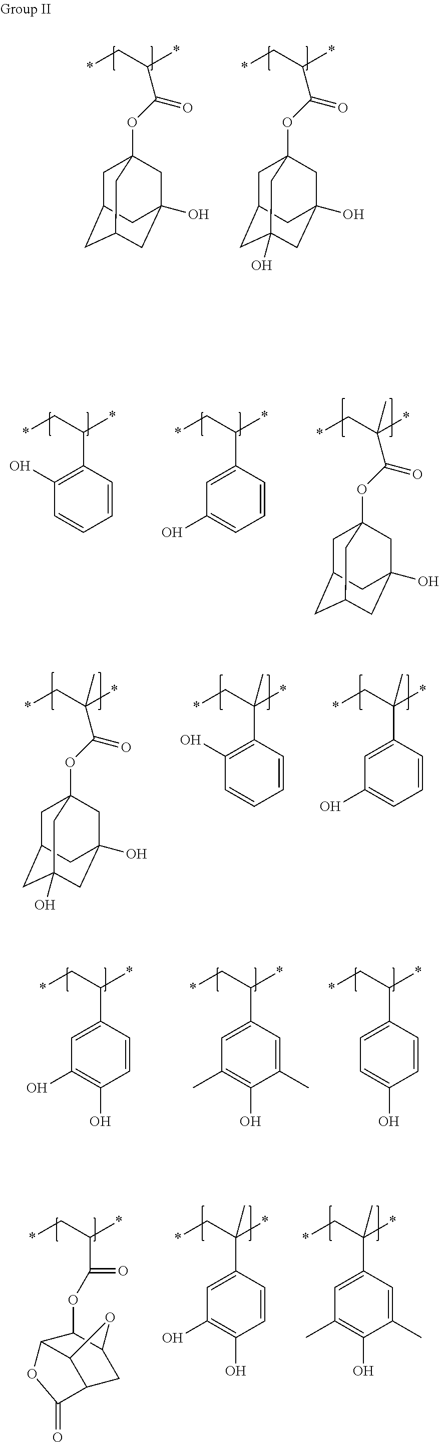

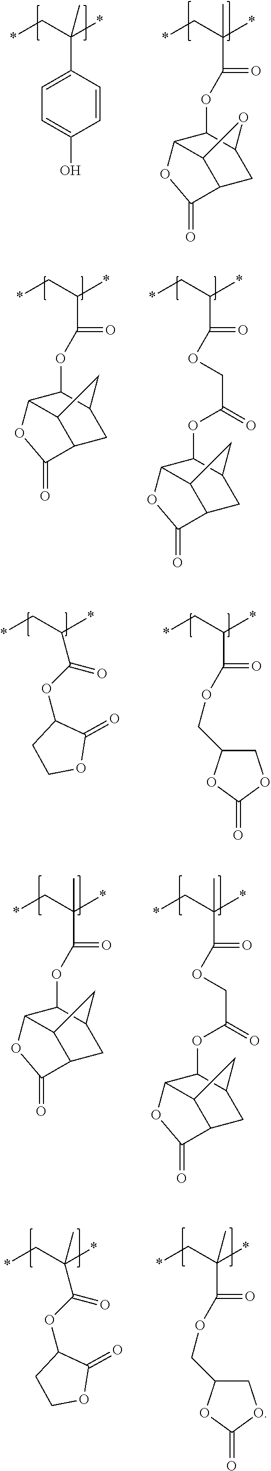

In an embodiment, the first chain of the polymer may include the first repeating unit in an amount of about 1 mol % to about 100 mol %, specifically about 5 mol % to about 100 mol %, and especially about 10 mol % to about 100 mol %.

In an embodiment, the second chain of the polymer may include the second repeating unit in an amount of about 1 to about 100 mol %, specifically about 5 to about 100 mol %, and especially about 10 to 100 mol %.

In an embodiment, the first chain of the polymer may include the third repeating unit in an amount of about 0 mol % to about 99 mol %, specifically about 1 mol % to about 99 mol %, and more specifically about 10 mol % to 90 mol %.

In an embodiment, the second chain of the polymer may include the third repeating unit in an amount of about 0 mol % to about 99 mol %, specifically about 1 mol % to about 99 mol %, and more specifically about 10 mol % to about 90 mol %.

In an embodiment, the first chain of the polymer may consist of the first repeating unit and the third repeating unit. For example, the first chain of the polymer may include the first repeating unit in an amount of about 1 mol % to about 99 mol %, specifically about 10 mol % to about 90 mol %, and the third repeating unit in an amount of about 1 mol % to about 99 mol %, specifically about 10 mol % to about 90 mol %.

In an embodiment, the second chain of the polymer may consist of the second repeating unit and the fourth repeating unit. For example, the second chain of the polymer may include the second repeating unit in an amount of about 1 mol % to about 99 mol %, specifically about 10 mol % to about 90 mol %, and the fourth repeating unit in an amount of about 1 mol % to about 99 mol %, specifically about 10 mol % to about 90 mol %.

The polymer may have a weight average molecular weight (Mw) of about 1,000 to about 500,000, specifically about 3,000 to about 100,000, and more specifically about 5,000 to about 50,000, as measured by gel permeation chromatography using a tetrahydrofuran solvent and polystyrene as a standard material.

A polydispersity index (PDI: Mw/Mn) of the polymer may be about 1.0 to about 3.0, specifically about 1.0 to about 2.5. Within these ranges, the possibility of foreign matter remaining on a pattern may be lowered, or deterioration of a pattern profile may be minimized. Accordingly, the resist composition may be more suitable for forming a fine pattern.

In addition, since the polymer has an acid labile group in a side chain, the solubility in a developer, particularly a basic developer that does not use an organic solvent, may increase as the side chain is decomposed by the acid generated from a photoacid generator.

Since the molecular weight of the polymer increases through the crosslinking unit, the solubility in a developer of an unexposed portion is relatively reduced compared to a polymer without crosslinking. Accordingly, an exposed portion of the polymer may be sufficiently dissolved in a developer, while the unexposed portion has improved dissolution resistance to the developer, so that the resolution of the polymer may be improved.

The polymer may have relatively high resistance to oxygen and/or moisture and a relatively high Tg (e.g., a Tg of about 80° C. or higher), and its physical properties may change only by high-energy rays, thereby providing a resist composition with improved storage stability, process stability, and the like.

The polymer may be manufactured by any suitable method, for example, by dissolving unsaturated bond-containing monomer(s) in an organic solvent and then performing a thermal polymerization in the presence of a radical initiator.

The structure (composition) of the polymer may be confirmed by performing Fourier transform infrared spectroscopy (FT-IR) analysis, nuclear magnetic resonance (NMR) analysis, X-ray fluorescence (XRF) analysis, mass spectrometry, ultraviolet (UV) analysis, single crystal X-ray structural analysis, powder X-ray diffraction (PXRD) analysis, liquid chromatography (LC) analysis, size exclusion chromatography (SEC) analysis, thermal analysis, and the like. The detailed verification method is as described in the following Examples.

### [Resist Composition]

According to another aspect, provided is a resist composition including the above-described polymer, a photoacid generator, and an organic solvent. The resist composition may have characteristics such as improved developability and/or improved resolution.

The solubility of the resist composition in a developer may change by exposure to high-energy rays. The resist composition may be a positive-type resist composition in which an exposed portion of a resist film is dissolved and removed to form a positive-type resist pattern, or a negative-type resist composition in which an unexposed portion of a resist film is dissolved and removed to form a negative-type resist pattern. Specifically, the resist composition may be a positive-type resist composition.

In addition, the resist composition according to an embodiment may be for an alkaline developing process using an alkaline developer for developing treatment when forming a resist pattern, or for a solvent developing process using a developer including an organic solvent for the developing treatment (hereinafter, also referred to as an organic developer). In particular, the resist composition according to an embodiment may be for an alkaline developing process.

The resist composition may not substantially include a compound having a molecular weight of about 1,000 or more other than the polymer, since the properties of the polymer may change by exposure.

The polymer may be used in an amount of about 0.1 parts by weight to about 80 parts by weight, based on 100 parts by weight of the resist composition. Specifically, the polymer may be used in an amount of about 0.5 parts by weight to about 5 parts by weight, based on 100 parts by weight of the resist composition. Within these ranges, any performance loss, for example, the formation of foreign particles due to a decrease in sensitivity and/or lack of solubility, may be reduced.

In addition, the polymer used in the resist composition may be used singly or in a combination of two or more.

Since the polymer is as described above, a photoacid generator, an organic solvent, and optional components, such as a quencher, included as needed will be described below.

### <Photoacid Generator>

The photoacid generator may be any compound capable of generating an acid when exposed to high-energy rays, such as ultraviolet (UV), deep ultraviolet (DUV), electron beam (EB), extreme ultraviolet (EUV), X-rays, a-rays, and y-rays.

The photoacid generator may include a sulfonium salt, an iodonium salt, and any combination thereof.

In an embodiment, the photoacid generator may be represented by Formula 7:

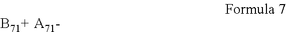

wherein, in Formula 7,
B₇₁⁺ is represented by Formula 7A, and A₇₁⁻ is represented by any one of Formulae 7B to 7D,
B₇₁⁺ and A₇₁⁻ may optionally be linked via a carbon-carbon covalent bond;

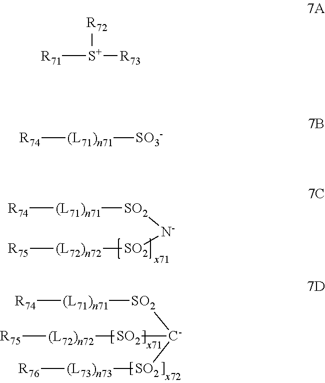

wherein, in Formulae 7A to 7D,
L₇₁ to L₇₃ may each independently be a single bond or CRR′,
R and R′ may each independently be hydrogen, deuterium, a halogen atom, a cyano group, a hydroxyl group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group,
n71 to n73 may each independently be 1, 2, or 3,
x71 and x72 may each independently be 0 or 1,
R₇₁ to R₇₃ may each independently be a linear, branched, or cyclic C₁-C₃₀ monovalent hydrocarbon group optionally including a heteroatom,
a neighboring two groups among R₇₁ to R₇₃ may optionally be bonded to each other to form a condensed ring, and
R₇₄ to R₇₆ may each independently be: hydrogen; halogen; or a linear, branched, or cyclic C₁-C₃₀ monovalent hydrocarbon group optionally including a heteroatom.

For example, in Formula 7, B₇₁⁺ is represented by Formula 7A, and A₇₁⁻ is represented by Formula 7B. Specifically, in Formula 7A, R₇₁ to R₇₃ may each be a phenyl group.

The photoacid generator may be included in an amount of about 0.01 parts by weight to about 40 parts by weight, about 0.1 parts by weight to about 40 parts by weight, or about 0.1 parts by weight to about 20 parts by weight, based on 100 parts by weight of the polymer. Within these ranges, appropriate levels of resolution may be achieved, and problems related to foreign matter particles after development or during stripping may be reduced.

The photoacid generator may be used singly or in a combination of two or more.

### <Solvent>

The solvent included in the resist composition is not particularly limited as long as the solvent is capable of dissolving or dispersing a polymer, a photoacid generator, and optional components such as a quencher included as needed.

The solvent may be used singly or in a combination of two or more.

The solvent may be an organic solvent or a mixed solvent in which water and an organic solvent are mixed.

Examples of the organic solvent may include an alcohol-based solvent, an ether-based solvent, a ketone-based solvent, an amide-based solvent, an ester-based solvent, a sulfoxide-based solvent, a hydrocarbon-based solvent, and the like.

More specifically, the alcohol-based solvent may include: a monoalcohol-based solvent, such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, and diacetone alcohol; a polyhydric alcohol-based solvent, such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, and tripropylene glycol; and a polyhydric alcohol-containing ether-based solvent, such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, and dipropylene glycol monopropyl ether.

Examples of the ether-based solvent may include: a dialkyl ether-based solvent, such as diethyl ether, dipropyl ether, dibutyl ether; a cyclic ether-based solvent, such as tetrahydrofuran and tetrahydropyran; and an aromatic ring-containing ether-based solvent, such as diphenyl ether and anisole.

Examples of the ketone-based solvent may include: a chain ketone-based solvent, such as acetone, methyl ethyl ketone, methyl-n-propyl ketone, methyl-n-butyl ketone, methyl-n-pentyl ketone, diethyl ketone, methyl isobutyl ketone, 2-heptanone, ethyl-n-butyl ketone, methyl-n-hexyl ketone, diisobutyl ketone, and trimethylnonanone; a cyclic ketone-based solvent, such as cyclopentanone, cyclohexanone, cycloheptanone, cyclooctanone, and methylcyclohexanone; and 2,4-pentanedione, acetonyl acetone, and acetophenone.

Examples of the amide-based solvent may include: a cyclic amide-based solvent, such as N, N′-dimethylimidazolidinone and N-methyl-2-pyrrolidone; and a chain amide-based solvent, such as N-methylformamide, N,N-dimethylformamide, N,N-diethylformamide, acetamide, N-methylacetamide, N,N-dimethylacetamide, and N-methylpropionamide.

Examples of the ester-based solvent may include: an acetate ester-based solvent, such as methyl acetate, ethyl acetate, n-propyl acetate, isopropyl acetate, n-butyl acetate, isobutyl acetate, sec-butyl acetate, t-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, and n-nonyl acetate; a polyhydric alcohol-containing ether carboxylate-based solvent, such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate (PGMEA), propylene glycol monoethyl ether acetate, propylene glycol monopropyl ether acetate, propylene glycol monobutyl ether acetate, dipropylene glycol monomethyl ether acetate, and dipropylene glycol monoethyl ether acetate; a lactone-based solvent, such as γ-butyrolactone and δ-valerolactone; a carbonate-based solvent, such as dimethyl carbonate, diethyl carbonate, ethylene carbonate, and propylene carbonate; a lactate ester-based solvent, such as methyl lactate, ethyl lactate, n-butyl lactate, and n-amyl lactate; and glycoldiacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, and diethyl phthalate.

Examples of the sulfoxide-based solvent may include dimethyl sulfoxide and diethyl sulfoxide.

Examples of the hydrocarbon-based solvent may include: an aliphatic hydrocarbon-based solvent, such as n-pentane, isopentane, n-hexane, isohexane, n-heptane, isoheptane, 2,2,4-trimethylpentane, n-octane, isooctane, cyclohexane, and methylcyclohexane; and an aromatic hydrocarbon-based solvent, such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, and n-amylnaphthalene.

Specifically, the organic solvent may be selected from an alcohol-based solvent, an amide-based solvent, an ester-based solvent, a sulfoxide-based solvent, and any combination thereof. More specifically, the solvent may be selected from propylene glycol monomethyl ether, propylene glycol monoethyl ether, propylene glycol monomethyl ether acetate, N-methyl-2-pyrrolidone, N,N-dimethylacetamide, ethyl lactate, dimethyl sulfoxide, and any combination thereof.

Meanwhile, when an acid labile group in the form of acetal is used, the organic solvent may further include a high-boiling alcohol, such as diethylene glycol, propylene glycol, glycerol, 1,4-butanediol, or 1,3-butanediol, to accelerate the deprotection reaction of the acetal.

The solvent may be used in an amount of about 200 parts by weight to about 20,000 parts by weight, specifically about 2,000 parts by weight to about 10,000 parts by weight, based on 100 parts by weight of the polymer.

### <Quencher>

The resist composition may further include a quencher.

The quencher may be a salt generating an acid that is less acidic than the acid generated from the photoacid generator.

The quencher may include an ammonium salt, a sulfonium salt, an iodonium salt, and any combination thereof.

In an embodiment, the quencher may be represented by Formula 8:

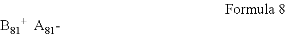

wherein, in Formula 8,
B₈₁⁺ is represented by any one of Formulae 8A to 8C, and A₈₁⁻ is represented by any one of Formulae 8D to 8F,

B₈₁⁺ and A₈₁⁻ may optionally be linked via a carbon-carbon covalent bond;

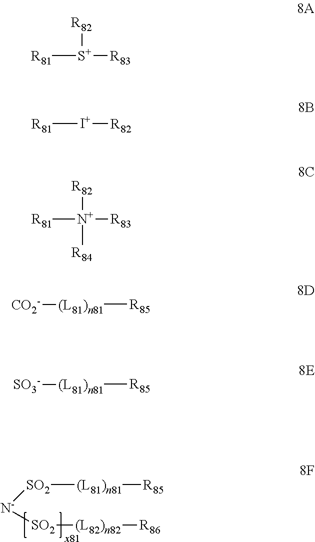

wherein, in Formulae 8A to 8F,
L₈₁ and L₈₂ may each independently be a single bond or CRR′,
R and R′ may each independently be hydrogen, deuterium, a halogen atom, a cyano group, a hydroxyl group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group,
n81 and n82 may each independently be 1, 2, or 3,
x81 may be 0 or 1,
R₈₁ to R₈₄ may each independently be a linear, branched, or cyclic C₁-C₃₀ monovalent hydrocarbon group optionally including a heteroatom,
a neighboring two groups among R₈₁ to R₈₄ may optionally be bonded to each other to form a condensed ring, and
R₈₅ and R₈₆ may be: hydrogen; halogen; or a linear, branched, or cyclic C₁-C₃₀ monovalent hydrocarbon group optionally including a heteroatom.

The quencher may be included in an amount of about 0 parts by weight to about 10 parts by weight, about 0.05 parts by weight to about 5 parts by weight, or about 0.1 parts by weight to about 3 parts by weight, based on 100 parts by weight of the polymer. Within these ranges, appropriate levels of resolution may be achieved, and problems related to foreign matter particles after development or during stripping may be reduced.

The quencher may be used singly or in a combination of two or more.

### <Optional Components>

The resist composition may further include a surfactant, a crosslinking agent, a leveling agent, a colorant, or any combination thereof as needed.

The resist composition may further include a surfactant to improve coatability, developability, and the like. Specific examples of the surfactant may include a nonionic surfactant, such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate. As the surfactant, a commercially available product or a synthetic product may be used. Examples of the commercially available product of the surfactant may include KP341 (manufactured by Shin-Etsu Chemical Co., Ltd.), Polyflow No. 75 and Polyflow No. 95 (manufactured by Kyoeisha Chemical Co., LTD.), Eftop EF301, Eftop 303, and Eftop 352 (manufactured by Mitsubishi Materials Electronic Chemicals Co., Ltd.), MEGAFACE™ F171, MEGAFACE™ F173, R-40, R-41, and R-43 (manufactured by DIC Corporation), FLUORAD™ FC430 and FLUORAD™ FC431 (manufactured by 3M, Co.,), ASAHI GUARD™ AG710 (manufactured by AGC Co., Ltd.), and SURFLON™ S-382, SURFLON™ SC-101, SURFLON™ SC-102, SURFLON™ SC-103, SURFLON™ SC-104, SURFLON™ SC-105, and SURFLON™ SC-106 (manufactured by AGC Seimi Chemical Co., Ltd.).

The surfactant may be included in an amount of about 0 parts by weight to about 20 parts by weight based on 100 parts by weight of the polymer.

The surfactant may be used singly or in a combination of two or more.

A method of manufacturing the resist composition is not particularly limited, and for example, a method of mixing a polymer, a photoacid generator, and optional components added as needed in an organic solvent, may be used. A temperature or time during mixing is not particularly limited. If necessary, filtration may be performed after mixing.

### [Pattern Formation Method]

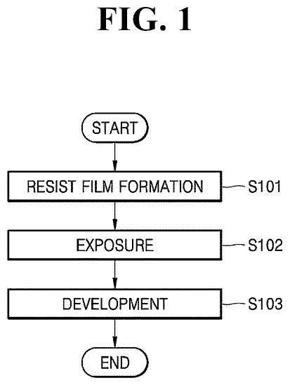

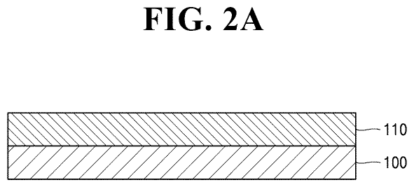

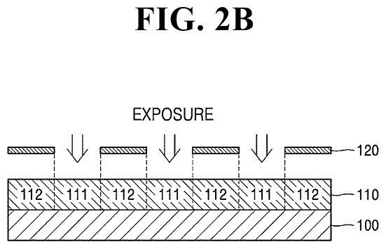

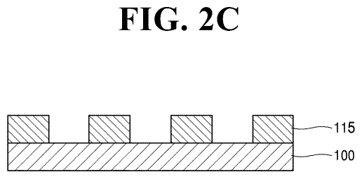

Hereinafter, a pattern formation method according to an embodiment will be described in more detail with reference to FIGS. 1 and 2A to 2C. FIG. 1 is a flowchart illustrating a pattern formation method according to an embodiment, and FIGS. 2A to 2C is a side cross-sectional view illustrating a pattern formation method according to an embodiment. Hereinafter, a pattern formation method using a positive-type resist composition as the resist composition will be described as an example, but is not limited thereto.

Referring to FIG. 1, the pattern formation method may include applying a resist composition onto a substrate to form a resist film S101, exposing at least a portion of the resist film to a high-energy ray S102, and developing the exposed resist film using a developer S103. Such operations may be omitted if necessary, or may be performed in a different order.

First, a substrate 100 may be prepared. The substrate 100 may include, for example, a semiconductor substrate such as a silicon substrate or a germanium substrate, glass, quartz, ceramic, copper, and the like. In some embodiments, the substrate 100 may include a Group Ill-Group V compound such as GaP, GaAs, and GaSb.

A resist composition may be applied to a desired thickness onto the substrate 100 by, specifically, coating, to form a resist film 110. If necessary, a post application bake (PAB) may be performed to remove a solvent remaining on the resist film 110.

As the coating method, spin coating, dipping, roller coating, or other general coating methods may be used. Among the coating methods, in particular, spin coating may be used, and the viscosity, concentration, and/or spin speed of the resist composition may be adjusted to form a resist film 110 having a desired thickness. Specifically, the thickness of the resist film 110 may be about 10 nm to about 300 nm. More specifically, the thickness of the resist film 110 may be about 30 nm to about 200 nm.

The lower limit of the temperature of the PAB may be about 60° C. or higher, specifically about 80° C. or higher. Additionally, the upper limit of the temperature of the PAB may be about 150° C. or less, specifically about 140° C. or less. The lower limit of the PAB time may be about 5 seconds or more, specifically about 10 seconds or more. The upper limit of the PAB time may be about 600 seconds or less, specifically about 300 seconds or less.

Before applying a resist composition onto a substrate 100, an etching target film (not shown) may be further formed on the substrate 100. The etching target film may refer to a layer on which an image is transferred from a resist pattern and converted into a predetermined pattern. In an embodiment, the etching target film may be formed to include, for example, an insulating material such as silicon oxide, silicon nitride, or silicon oxynitride. In some embodiments, the etching target film may be formed to include a conductive material such as a metal, metal nitride, metal silicide, or metal silicide nitride. In some embodiments, the etching target film may be formed to include a semiconductor material such as polysilicon.

In an embodiment, an antireflection film may be further formed on the substrate 100 to improve and/or maximize the efficiency of a resist. The antireflection film may be an organic or inorganic antireflection film.

In an embodiment, a protective film may be further provided on the resist film 110 to reduce the influence of alkaline impurities or the like included during a process. In addition, when immersion exposure is performed, for example, a protective film for immersion may be provided on the resist film 100 to avoid direct contact between an immersion medium and the resist film 110.

Next, at least a portion of the resist film 110 may be exposed to a high-energy ray. For example, a high-energy ray passing through a mask 120 may be irradiated onto at least a portion of the resist film 110. Accordingly, the resist film 110 may have an exposed portion 111 and an unexposed portion 112.

Although not limited to a specific theory, the properties of the resist composition may change as the main chain of the polymer within the exposed portion 111 is decomposed by the acid generated by exposure.

In some cases, the exposure may be performed by irradiating a high-energy ray through a mask with a certain pattern using a liquid such as water as a medium. Examples of the high-energy ray may include: an electromagnetic wave such as an ultraviolet ray, a deep ultraviolet (DUV) ray, an extreme ultraviolet (EUV) ray (with a wavelength of 13.5 nm), an X-ray, and a γ-ray; and a charged particle beam such as an electron beam (EB) and an α-ray, and the like. Irradiating the high-energy ray may be collectively referred to as “exposure.”

As the method using the exposure light source, various methods may be used including emitting laser light in the ultraviolet light region, such as KrF excimer lasers (wavelength 248 nm), ArF excimer lasers (wavelength 193 nm), and F₂ excimer lasers (wavelength 157 nm), emitting harmonic laser light in the deep ultraviolet region or vacuum ultraviolet region by converting the wavelength of laser light from solid-state laser sources (such as YAG or semiconductor lasers), and irradiating electron beams or EUV rays. During exposure, the exposure may be usually performed through a mask corresponding to a desired pattern, but when exposure light source is an electron beam, the exposure may be performed through direct writing without using a mask.

When an extreme ultraviolet ray are used as the high-energy ray, the integrated dose of the high-energy ray may be about 2000 mJ/cm² or less, specifically about 500 mJ/cm² or less. In addition, when an EB are used as the high-energy ray, the integrated dose may be about 5000 μC/cm² or less, specifically about 1000 μC/cm² or less.

In addition, post exposure bake (PEB) may be performed. The lower limit of the temperature of PEB may be about 50° C. or higher, specifically about 80° C. or higher. The upper limit of the temperature of PEB may be about 180° C. or less, specifically about 130° C. or less. The lower limit of the PEB time may be about 5 seconds or more, specifically about 10 seconds or more. The upper limit of the PEB time may be about 600 seconds or less, specifically about 300 seconds or less.

Next, the exposed resist film 110 may be developed using a developer. The exposed portion 111 may be washed away by the developer, and the unexposed portion 112 may remain without being washed away by the developer.

Examples of the developer may include an alkaline developer, a developer including an organic solvent (hereinafter also referred to as “organic developer”), and the like. Examples of a developing method may include a dipping method, a puddle method, a spray method, a dynamic injection method, and the like. A developing temperature may be, for example, about 5° C. to about 60° C., and a developing time may be, for example, about 5 seconds to about 300 seconds.

The alkaline developer may include, for example, an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, tetramethylammonium hydroxide (TMAH), pyrrole, piperidine, choline, 1,8-diazabicyclo[5.4.0]-7-undecene (DBU), and 1,5-diazabicyclo[4.3.0]-5-nonene (DBN) are dissolved. The alkali developer may further include a surfactant.

The lower limit of the amount of the alkaline compound in the alkaline developer may be about 0.1 wt % or more, specifically about 0.5 wt % or more, and more specifically about 1 wt % or more. Additionally, the upper limit of the amount of the alkaline compound in the alkaline developer may be about 20 wt % or less, specifically about 10 wt % or less, and more specifically about 5 wt % or less.

After development, the resist pattern 115 may be cleaned with ultrapure water, and then water remaining on the substrate and pattern may be removed therefrom.

Examples of the organic solvent included in the organic developer may include the same organic solvents as those examples in the part of <Solvent> of [Resist composition].

The lower limit of the amount of the organic solvent in the organic developer may be about 80 wt % or more, specifically about 90 wt % or more, more specifically about 95 wt % or more, and especially about 99 wt % or more.

The organic developer may also include a surfactant. In addition, a trace amount of water may be included in the organic developer. Additionally, during development, development may be stopped by substitution with a different kind of solvent from the organic developer.

The resist pattern 115 after the development may be further cleaned. Ultrapure water, a rinse solution, and the like may be used as a cleaning solution. A rinse solution is not particularly limited as long as the rinse solution does not dissolve a resist pattern, and a solution including a general organic solvent may be used. For example, the rinse solution may be an alcohol-based solvent or an ester-based solvent. After the cleaning, the rinse solution remaining on the substrate and pattern may be removed. In addition, when the ultrapure water is used, water remaining on the substrate and pattern may be removed.

In addition, developers may be used singly or in a combination of two or more.

After the resist pattern is formed as described above, a pattern interconnection substrate may be obtained through etching. The etching may be performed through a known method including dry etching using a plasma gas and wet etching using an alkaline solution, a copper (II) chloride solution, an iron (II) chloride solution, and the like.

After the resist pattern is formed, plating may be performed. The plating is not particularly limited, and examples thereof may include copper plating, solder plating, nickel plating, gold plating, and the like.

The resist pattern remaining after the etching may be peeled off with an organic solvent. Examples of such organic solvent may include, but are not limited to, propylene glycol monomethyl ether acetate (PGMEA), propylene glycol monomethyl ether (PGME), ethyl lactate (EL), and the like. A peeling method is not particularly limited, but examples thereof may include an immersion method, a spray method, and the like. In addition, the interconnection substrate on which the resist pattern is formed may be a multilayer interconnection substrate or may have small-diameter through-holes.

In an embodiment, the interconnection substrate may be formed through a method of forming a resist pattern, depositing a metal in a vacuum, and then melting the resist pattern with a solution, that is, a lift-off method.

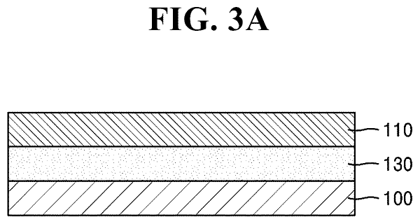

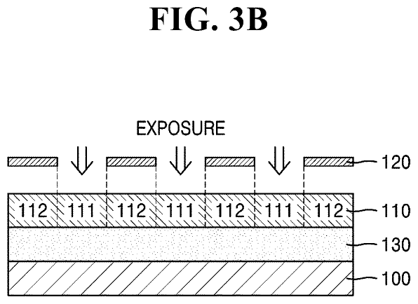

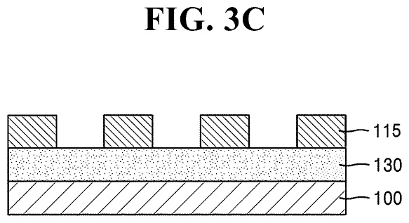

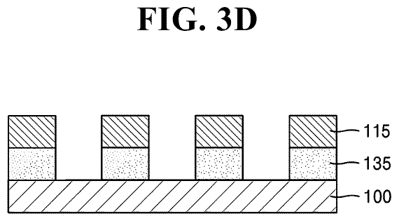

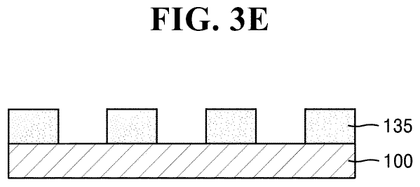

FIGS. 3A to 3E are side cross-sectional views illustrating a method of forming a patterned structure according to an embodiment;

As shown in FIG. 3A, a material layer 130 may be formed on a substrate 100 before forming a resist film 110 on the substrate 100. The resist film 110 may be formed on the material layer 130. The material layer 130 may include an insulating material (e.g., silicon oxide, silicon nitride), a semiconductor material (e.g., silicon), or a metal (e.g., copper). In some embodiments, the material layer 130 may have a multilayer structure. The material of the material layer 130 may be different from the material of the substrate 100.

As shown in FIG. 3B, the resist film 110 may be exposed to a high-energy ray through a mask 120 after undergoing a prebake process before exposure, and then the resist film 110 may include an exposed portion 111 and an unexposed portion 112.

As shown in FIG. 3C, the exposed resist film 110 may be developed using a developer (e.g., a developing solution). The exposed portion 111 may be washed away by the developer, and the unexposed portion 112 may remain without being washed away by the developer.

As shown in FIG. 3D, a material pattern 135 may be formed on a substrate 100 by etching an exposed portion of a material layer 130 using a resist pattern 115 as a mask.

As shown in FIG. 3E, the resist pattern 115 may be removed.

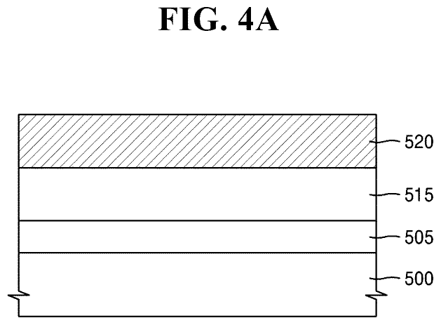

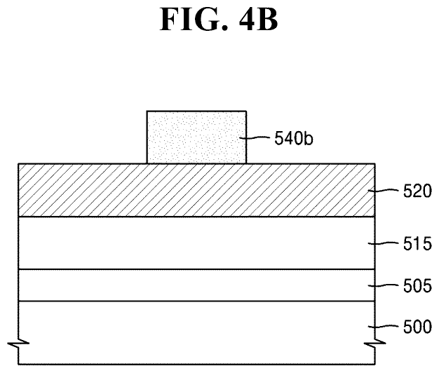

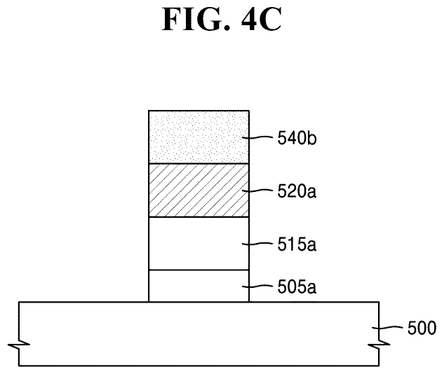

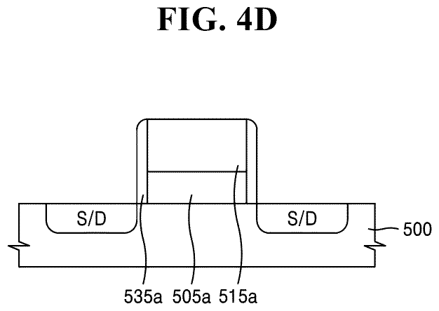

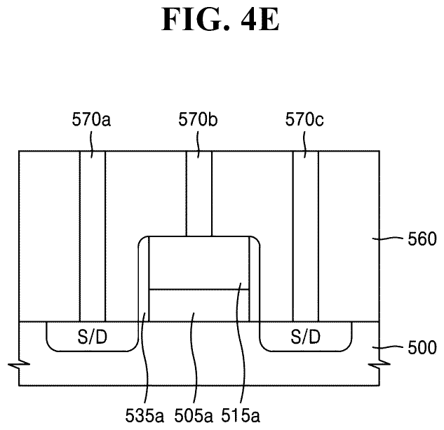

FIGS. 4A to 4E are side cross-sectional views illustrating a method of forming a semiconductor device according to an embodiment.

As shown in FIG. 4A, a gate dielectric 505 (e.g., silicon oxide) may be formed on a substrate 500. The substrate 500 may be a semiconductor substrate such as a silicon substrate. A gate layer 515 (e.g., doped polysilicon) may be formed on the gate dielectric 505. A hardmask layer 520 may be formed on the gate layer 515.

As shown in FIG. 4B, a resist pattern 540b may be formed on the hardmask layer 520. A resist pattern 540b may be formed using a resist composition according to an embodiment. The resist composition may include an organic solvent. The resist composition may include a photoacid generator. The resist composition may include a quencher.

As shown in FIG. 4C, the gate layer 515 and the gate dielectric 505 may be etched to form a hardmask pattern 520a, a gate electrode pattern 515a, and a gate dielectric pattern 505a.

As shown in FIG. 4D, the hardmask pattern 520a optionally may be removed. A spacer layer may be formed on the gate electrode pattern 515a and the gate dielectric pattern 505a. The spacer layer may be formed using a deposition process (e.g., chemical vapor deposition (CVD)). The spacer layer may be etched to form a spacers 535a (e.g., silicon nitride) on sidewalls of the gate electrode pattern 515a and the gate dielectric pattern 505a. After forming the spacers 535a, ions may be implanted into the substrate 500 to form source/drain impurity regions S/D.

As shown FIG. 4E, an interlayer insulating layer 560 (e.g., oxide) may be formed on the substrate 500 to cover the gate electrode pattern 515a, the gate dielectric pattern 505a, and the spacers 535a. Then, electrical contacts 570a, 570b, and 570c connected to the gate electrode 515a and the S/D regions may be formed in the interlayer insulating layer 560. The electrical contacts 570a, 570b, and 570c may be formed of a conductive material (e.g., metal). Although not shown, a barrier layer may be formed between sidewalls of the interlayer insulating layer 560 and the electrical contacts 570a, 570b, and 570c.

While FIGS. 4A to 4E illustrate an example of forming a transistor, the disclosure is not limited thereto.

For example, although not illustrated in FIGS. 4D and 4E, in some embodiments, the hard mask pattern 520a may not be removed before the spacer 535a is formed. For example, if the hard mask pattern 520a is not removed, then the hard mask pattern 520a may remain on top of the gate electrode 515a in FIGS. 4D and 4E, the spacer 535a may cover a sidewall of the hard mask pattern 520a in FIGS. 4D and 4E, and the electrical contact 570b may extend through an opening in the hard mask pattern 520a to directly contact an upper surface of the gate electrode 515a.

A resist composition according to an embodiment may be used in a patterning process to form other types of semiconductor devices.

The disclosure will be described in more detail using the following Examples and Comparative Examples, but the technical scope of the disclosure is not limited only to the following Examples.

### EXAMPLES

### Comparative Synthesis Example 1: Synthesis of Polymer HS/ECPMA

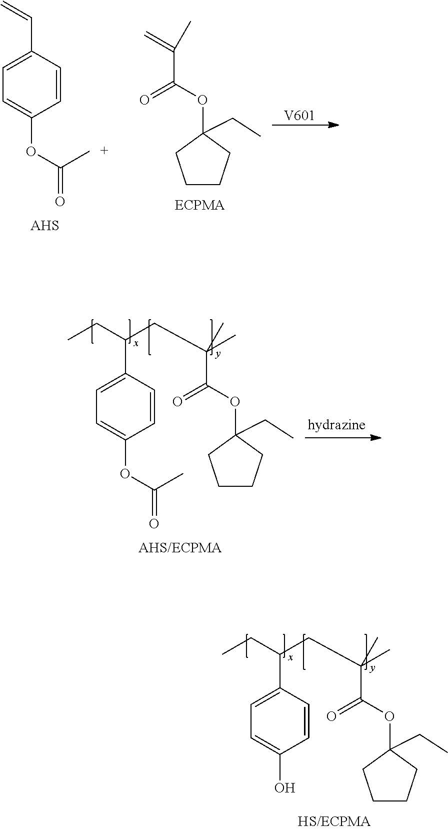

Acetoxystyrene (AHS) (1.5 g, 9.3 mmol), 2-ethyl-2-cyclopentyl methacrylate (ECPMA) (1.7 g, 9.3 mmol), and Dimethyl 2,2′-azobis(2-methylpropionate) (V601) (0.2 g, 0.9 mmol) were dissolved in 18 mL of dioxane and reacted at 80° C. for 4 hours. Hydrazine monohydrate (1 g) was added to the reaction mixture, and the resulting mixture was further reacted for 2 hours at room temperature. After adding 50 mL of distilled water and 2 g of acetic acid thereto, the reaction mixture was subjected to an extraction process using ethyl acetate, the solvent was removed from the collected organic layer, and the resulting product was precipitated again using hexane. The obtained solid was dried at 40° C. for 24 hours to obtain Polymer HS/ECPMA (molar ratio=50/50) with a molecular weight (Mw) of 5,056 g/mol and a PDI of 1.3.

### Synthesis Example 1: Synthesis of Polymer E-HS/ECPMA1

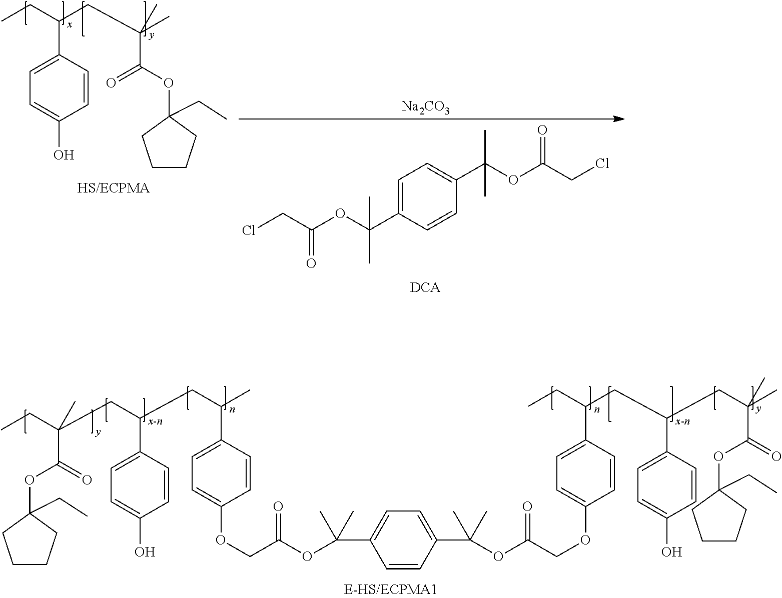

Polymer HS/ECPMA obtained in Comparative Synthesis Example 1 and 2-[4-[2-(2-chloroacetyl)oxypropan-2-yl]phenyl]propan-2-yl 2-chloroacetate(DCA) were dissolved in dimethylformamide (DMF) at a weight ratio of 1:0.05. Sodium carbonate was added thereto at a molar ratio of 10:1 with respect to the DCA. The reaction was then performed for 24 hours.

After the reaction, the reaction mixture was precipitated in water, extracted with ethyl acetate, the solvent was removed from the collected organic layer, and then precipitation was performed again using hexane. The obtained solid was dried at 40° C. for 24 hours to obtain Polymer E-HS/ECPMA1.

### Synthesis Examples 2 to 4: Synthesis of Polymer E-HS/ECPMA2 to Polymer E-HS/ECPMA4

Polymers E-HS/ECPMA2, E-HS/ECPMA3, and E-HS/ECPMA4 were synthesized using the same method as in Synthesis Example 1, except that DCA was used at the weight ratios shown in Table 1 below.

TABLE 1

| | | | | —OH |
|---|---|---|---|---|
| | HS/ECPMA:DCA | | | blocking |
| Polymer | (weight ratio) | Mw | PDI | (%) |
| HS/ECPMA | 0 | 5056 | 1.3 | 0 |
| E-HS/ECPMA1 | 1:0.05 | 7794 | 1.6 | 6 |
| E-HS/ECPMA2 | 1:0.10 | 9009 | 1.8 | 12 |
| E-HS/ECPMA3 | 1:0.20 | 12441 | 1.9 | 21 |
| E-HS/ECPMA4 | 1:0.30 | 13542 | 1.8 | 26 |

In the above Table 1, —OH blocking (%) is a value calculated from the ratio of peaks corresponding to “OH” in the ¹H-NMR data of each polymer. As shown in Table 1, it was confirmed that as the amount of DCA added during the reaction increased, it reacted more with the —OH of hydroxystyrene, thereby increasing the —OH blocking (%).

### Comparative Synthesis Example 2: Synthesis of Polymer X

To synthesize Polymer X in which the ester group in the linker of Polymer E-HS/ECPMA1 was changed to an acetal group, HS/ECPMA and 1,4-cyclohexanedimethanol divinyl ether were dissolved in DMF at a weight ratio of 1:0.05, and the reaction was performed at 130° C. After about an hour, gelation occurred so that the final Polymer X could not be obtained. Because Polymer X could not be obtained, evaluation of thin film development and the like could not be performed.

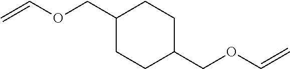

### 1,4-cyclohexanedimethanol Divinyl Ether

### Evaluation Example 1: Evaluation of Thin Film Development

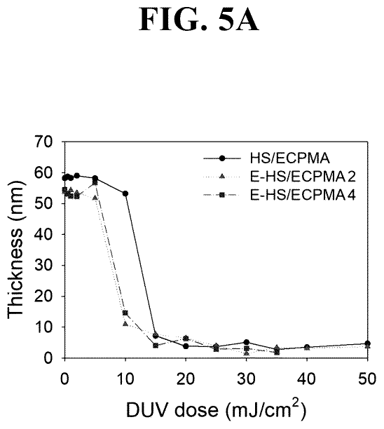

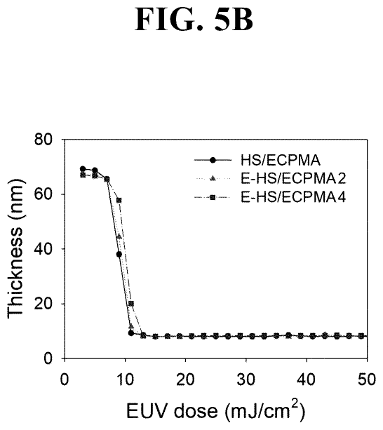

Each of Polymers HS/ECPMA, E-HS/ECPMA2, and E-HS/ECPMA4 synthesized in Comparative Synthesis Example 1 and Synthesis Examples 2 and 4 was dissolved in an amount of 1.6 wt % in a casting solvent, which is a 7/3 (wt/wt) solution of PGME/PGMEA, and then 0.024 mmol of PAG and 0.016 mmol of PDQ were added thereto. A silicon wafer treated with hexamethyldisilazane (HMDS) was spin-coated with a casting solution at a speed of 1500 rpm, followed by performing post application bake (PAB) at 110° C. for 1 minute to manufacture a film. Next, the film was exposed to a deep ultraviolet (DUV) with a wavelength of 248 nm or an extreme ultraviolet (EUV) with a wavelength of 13.5 nm at a dose of 0 to 50 mJ/cm², a post exposure bake was performed thereon at 90° C. for 60 seconds, and immersed in a 2.38 wt % tetramethylammonium hydroxide (TMAH) aqueous solution at 25° C. for 20 seconds. Then, the portion exposed to the high-energy ray was removed by rinsing with deionized (DI) water for 10 seconds, and dried. The remaining film thickness was measured by using a film thickness measurement instrument (Filmetrics©, F-20), and the results are shown in FIGS. 5A and 5B. FIG. 5A is the DUV result, and FIG. 5B is the EUV result.

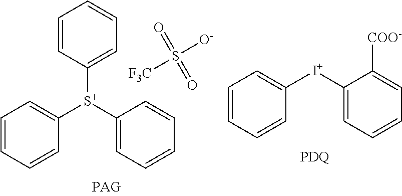

From this, it was confirmed that the solubility of Polymers E-HS/ECPMA2 and E-HS/ECPMA4 changed by DUV or EUV in a similar manner to HS/ECPMA.

### Evaluation Example 2: Evaluation of Molecular Weight Change

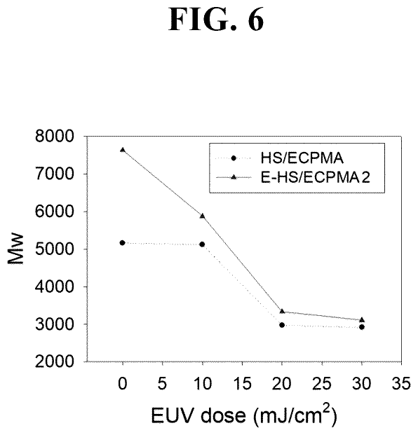

Each of the polymers synthesized in Comparative Synthesis Example 1 and Synthesis Example 2 was dissolved in an amount of 1.6 wt % in a casting solvent, which is a 7/3 (wt/wt) solution of PGME/PGMEA, and then 0.024 mmol of PAG and 0.016 mmol of PDQ were added thereto. After exposure to EUV with a wavelength of 13.5 nm at a dose of 0 mJ/cm² to 50 mJ/cm², gel permeation chromatography (GPC) analysis was performed, and the change in molecular weight is shown in FIG. 6.

Referring to FIG. 6, it was confirmed that the molecular weight of Polymer HS/ECPMA was decreased due to the elimination of the acid labile group, and that the molecular weight of Polymer E-HS/ECPMA2 changed to the molecular weight level of HS/ECPMA at a dose of 10 mJ/cm², and then finally was decreased due to the elimination of the acid labile group.

### Evaluation Example 3: Evaluation of Solubility in Developer

Each of the polymers synthesized in Comparative Synthesis Example 1 and Synthesis Examples 2 and 4 was dissolved in an amount of 1.6 wt % in a casting solvent, which is a 7/3 (wt/wt) solution of PGME/PGMEA, and then 0.024 mmol of PAG and 0.016 mmol of PDQ were added thereto. A silicon wafer treated with HMDS was spin-coated with a casting solution at a speed of 1500 rpm, and then was dried (PAB) at 110° C. for 1 minute to manufacture a film. Next, the film was exposed to DUV with a wavelength of 248 nm or EUV with a wavelength of 13.5 nm at a dose of 0 mJ/cm² to 50 mJ/cm², a post exposure bake was performed at 90° C. for 60 seconds to prepare a thin film.

Next, the thin film was immersed in a 2.38 wt % TMAH solution for 20 seconds, 40 seconds, and 60 seconds, and the slope obtained from the graph of the change in the thickness of the thin film according to the immersion time was confirmed to derive Rmin.

In addition, the thin film was immersed in a 0.00238 wt % TMAH solution for 10 seconds, 20 seconds, and 30 seconds, and the slope obtained from the graph of the change in the thickness of the thin film according to the immersion time was confirmed to derive Rmax.

Here, Rmin represents a dissolution rate for the unexposed portion, and Rmax represents a dissolution rate after exposure.

Next, each Rmin and Rmax obtained from Polymers E-HS/ECPMA2 and E-HS/ECPMA4 were calculated as relative values of Rmin and Rmax obtained from Polymer HS/ECPMA, and then shown as R·Rmin and R·Rmax in Table 2 below.

TABLE 2

| Polymer | R.Rmin | R.Rmax |
|---|---|---|
| HS/ECPMA | 1.00 | 1.00 |
| E-HS/ECPMA2 | 0.82 | 1.52 |
| E-HS/ECPMA4 | 0.48 | 2.34 |

Referring to Table 2 above, it was confirmed that Polymer E-HS/ECPMA2 and Polymer E-HS/ECPMA4, of which molecular weights were increased through crosslinking, had significantly lower solubility in the developer in the unexposed portion than Polymer HS/ECPMA, whereas the solubility in the developer in the exposed portion was significantly increased than Polymer HS/ECPMA. This suggests that Polymer E-HS/ECPMA2 and Polymer E-HS/ECPMA4 can exhibit significantly improved resolution compared to Polymer HS/ECPMA.

Embodiments can provide a resist composition having improved sensitivity and/or resolution.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A polymer comprising:
a first chain comprising a first repeating unit represented by Formula 1;
a second chain comprising a second repeating unit represented by Formula 2; and
a crosslinking unit represented by Formula 9, the crosslinking unit linking the first chain and the second chain, 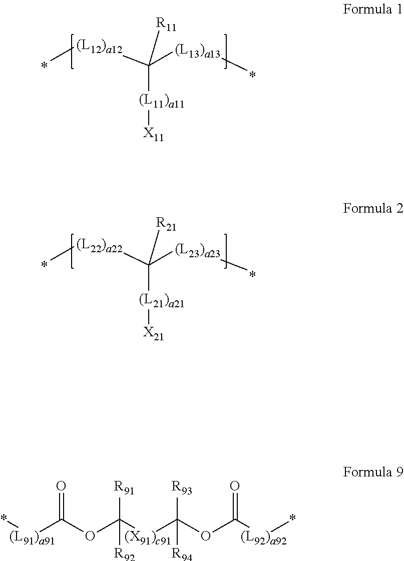
wherein, in Formulae 1, 2, and 9,
L₁₁ to L₁₃ are each independently: a single bond; O; S; C(═O); C(═O)O; OC(═O); C(═O)NR₁₂; NR₁₂C(═O); S(═O); S(═O)₂O; OS(═O)₂; or a linear, branched, or cyclic C₁-C₃₀ divalent hydrocarbon group optionally including a heteroatom,
L₂₁ to L₂₃ are each independently: a single bond; O; S; C(═O); C(═O)O; OC(═O); C(═O)NR₂₂; NR₂₂C(═O); S(═O); S(═O)₂O; OS(═O)₂; or a linear, branched, or cyclic C₁-C₃₀ divalent hydrocarbon group optionally including a heteroatom,
a11 to a13 and a21 to a23 are each independently an integer from 1 to 4,
R₁₁, R₁₂, R₂₁, and R₂₂ are each independently: hydrogen; deuterium; a halogen atom; a cyano group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched, or cyclic C₁-C₃₀ monovalent hydrocarbon group optionally including a heteroatom,
X₁₁ and X₂₁ are each independently an acid labile group,
L₁₁ and L₉₂ are each independently: a single bond; or a linear, branched, or cyclic C₁-C₃₀ divalent hydrocarbon group optionally including a heteroatom,
a91 and a92 are each independently an integer from 1 to 4,
R₉₁ to R₉₄ are each independently a linear, branched, or cyclic C₁-C₃₀ monovalent hydrocarbon group optionally including a heteroatom, and R₉₁ and R₉₂ or R₉₃ and R₉₄ are optionally bonded to each other to form a ring,
X₉₁ is a linear, branched, or cyclic C₁-C₃₀ divalent hydrocarbon group optionally including a heteroatom,
c91 is an integer from 1 to 4, and
* indicates a binding site to a neighboring atom.

2. The polymer of claim 1,
wherein R₁₁ and R₂₁ are each independently selected from: hydrogen; deuterium; a halogen atom; a cyano group; a hydroxyl group; an amino group; a carboxylate group; a thiol group; and a C₁-C₂₀ alkyl group, a C₃-C₂₀ cycloalkyl group, and a C₆-C₂₀ aryl group, each unsubstituted or substituted with deuterium, a halogen atom, a cyano group, a hydroxyl group, an amino group, a carboxylate group, a thiol group, an ester moiety, a sulfonate moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof,
R₁₂ and R₂₂ are each independently: hydrogen, deuterium, a halogen atom, a cyano group, a hydroxyl group, an amino group, a carboxylate group, a thiol group, a C₁-C₂₀ alkyl group, a C₁-C₂₀ halogenated alkyl group, a C₃-C₂₀ cycloalkyl group, or a C₆-C₂₀ aryl group,
X₁₁ and X₂₁ are each independently represented by any one of Formulae 6-1 to 6-12: 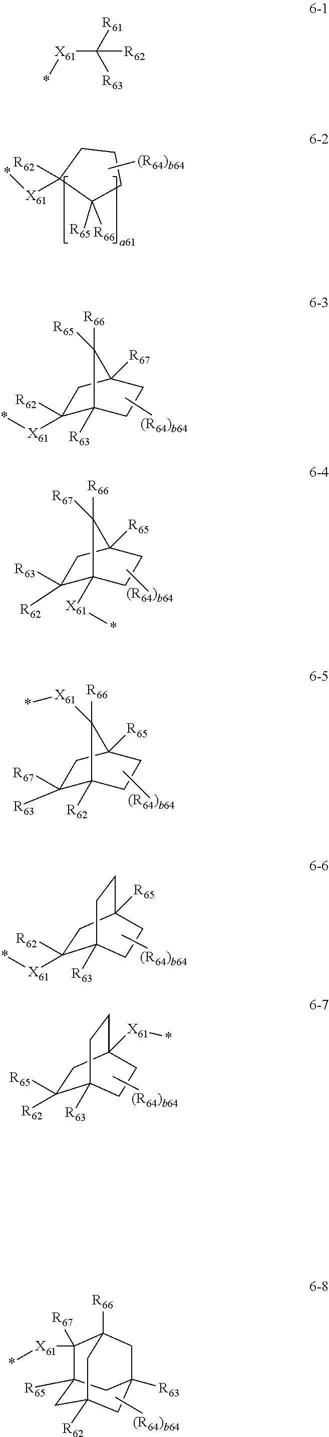 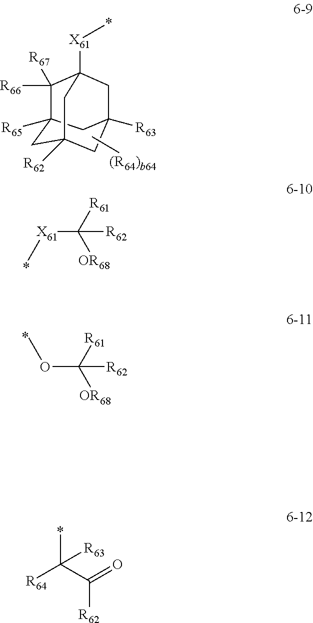
wherein, in Formulae 6-1 to 6-12,
X₆₁ is an ester moiety, a sulfonate moiety, a carbonate moiety, or a carbamate moiety;
a61 is an integer from 0 to 6;
R₆₁ and R₆₈ are each independently a linear, branched, or cyclic C₁-C₂₀ monovalent hydrocarbon group optionally including a heteroatom,
R₆₂ to R₆₇ are each independently: hydrogen; deuterium; a halogen atom; a cyano group; a hydroxyl group; an amino group; a carboxylate group; a thiol group; an ester moiety; a sulfonate moiety; a carbonate moiety; a carbamate moiety; a lactone moiety; a sultone moiety; a carboxylic anhydride moiety; or a linear, branched, or cyclic C₁-C₃₀ monovalent hydrocarbon group optionally including a heteroatom,
a neighboring two groups among R₆₁ to R₆₈ are optionally bonded to each other to form a ring,
b64 is an integer from 1 to 10, and
* indicates a binding site to a neighboring atom.

3. The polymer of claim 1,
wherein the first repeating unit and the second repeating unit are each independently selected from Group I:

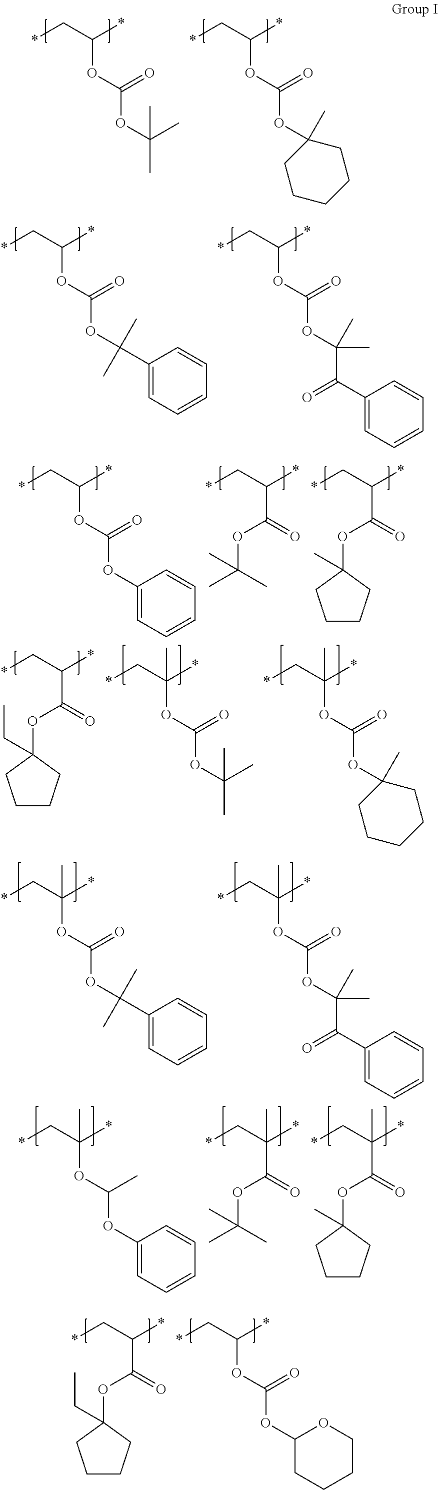

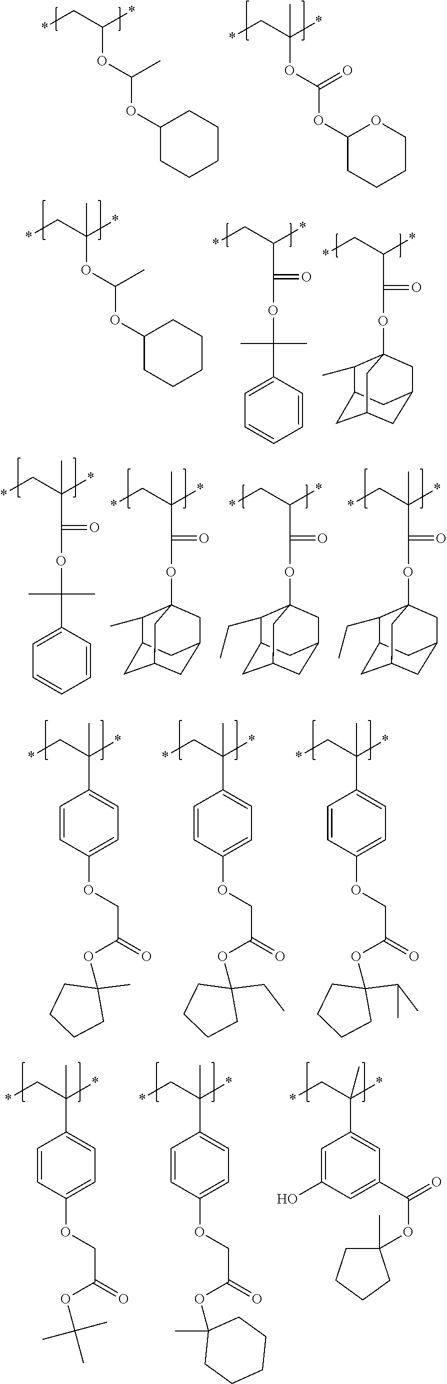

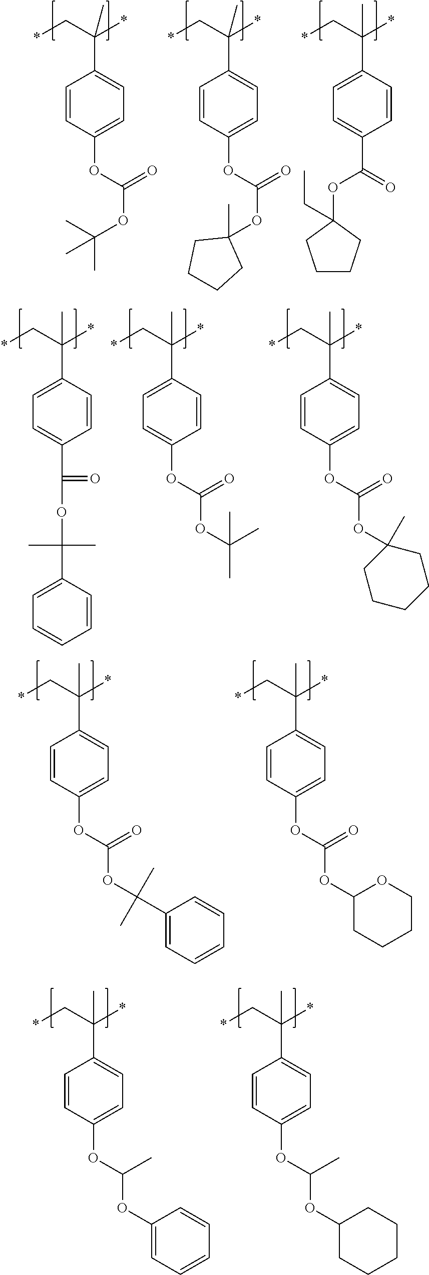

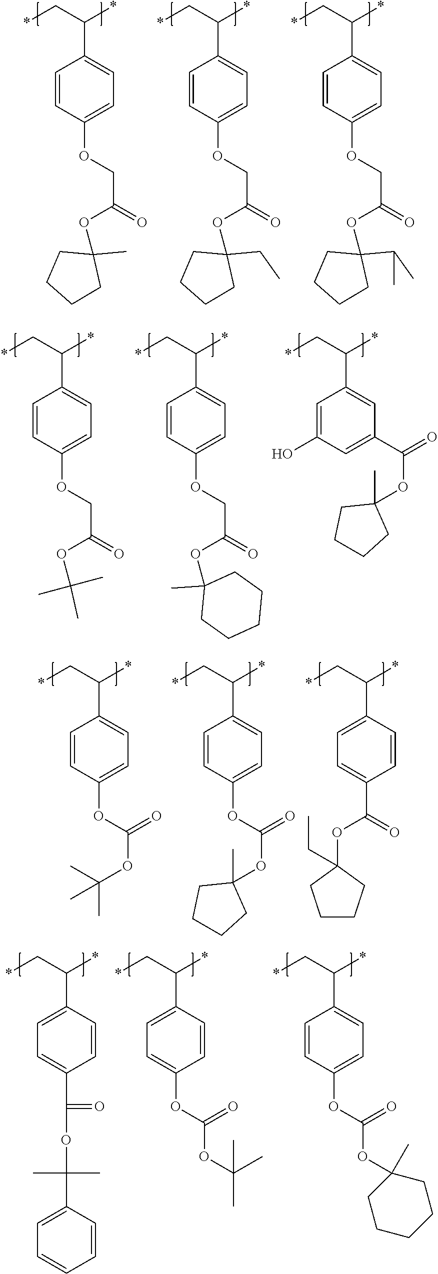

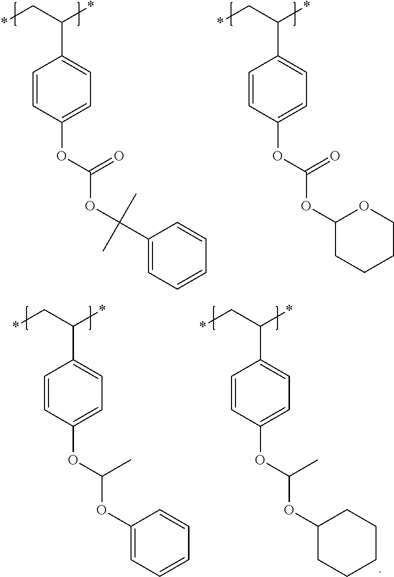

4. The polymer of claim 1,
wherein L₉₁ and L₉₂ are each independently: a single bond; a substituted or unsubstituted C₁-C₃₀ alkylene group; a substituted or unsubstituted C₃-C₃₀ cycloalkylene group; a substituted or unsubstituted C₃-C₃₀ heterocycloalkylene group; a substituted or unsubstituted C₂-C₃₀ alkenylene group; a substituted or unsubstituted C₃-C₃₀ cycloalkenylene group; a substituted or unsubstituted C₃-C₃₀ heterocycloalkenylene group; a substituted or unsubstituted C₆-C₃₀ arylene group; or a substituted or unsubstituted C₁-C₃₀ heteroarylene group.

5. The polymer of claim 1,
wherein X₉₁ is selected from a C₁-C₂₀ alkylene group, a C₃-C₂₀ cycloalkylene group, a C₂-C₂₀ alkenylene group, a C₃-C₂₀ cycloalkenylene group, and a C₆-C₂₀ arylene group, each unsubstituted or substituted with deuterium, a halogen atom, a cyano group, a nitro group, a hydroxyl group, an amino group, a carboxylate group, a thiol group, a C₁-C₂₀ alkyl group, a C₁-C₂₀ halogenated alkyl group, a C₁-C₂₀ alkoxy group, or any combination thereof.

6. The polymer of claim 1,
wherein c91 is 1.

7. The polymer of claim 1,
wherein the crosslinking unit is selected from Group III:
Group III

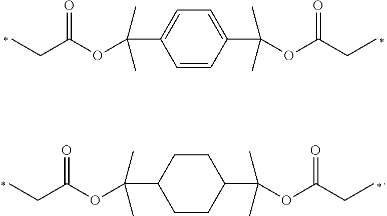

8. The polymer of claim 1,
wherein the polymer comprises the crosslinking unit in an amount of about 0.1 parts by weight to about 50 parts by weight based on 100 parts by weight of the polymer.

9. The polymer of claim 1, wherein
the first chain further comprises a third repeating unit represented by Formula 3,
the second chain further comprises a fourth repeating unit represented by Formula 4, or
the first chain further comprises the third repeating unit represented by Formula 3, and the second chain further comprises the fourth repeating unit represented by Formula 4, 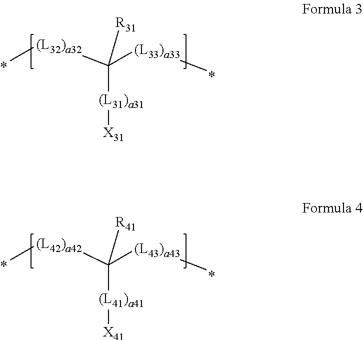
wherein, in Formulae 3 and 4,
L₃₁ to L₃₃ are each independently: a single bond; O; S; C(═O); C(═O)O; OC(═O); C(═O)NR₃₂; NR₃₂C(═O); S(═O); S(═O)₂O; OS(═O)₂; or a linear, branched, or cyclic C₁-C₃₀ divalent hydrocarbon group optionally including a heteroatom,
L₄₁ to L₄₃ are each independently: a single bond; O; S; C(═O); C(═O)O; OC(═O); C(═O)NR₄₂; NR₄₂C(═O); S(═O); S(═O)₂O; OS(═O)₂; or a linear, branched, or cyclic C₁-C₃₀ divalent hydrocarbon group optionally including a heteroatom,
a31 to a33 and a41 to a43 are each independently an integer from 1 to 4,
R₃₁, R₃₂, R₄₁, and R₄₂ are each independently: hydrogen; deuterium; a halogen atom; a cyano group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched, or cyclic C₁-C₃₀ monovalent hydrocarbon group optionally including a heteroatom,
X₃₁ and X₄₁ are each independently a non-acid labile group, and
* indicates a binding site to a neighboring atom.

10. The polymer of claim 9,
wherein X₃₁ and X₄₁ are each independently: hydrogen; deuterium; a halogen atom; a cyano group; a hydroxyl group; an amino group; a carboxylate group; a thiol group; or a linear, branched, or cyclic C₁-C₃₀ monovalent hydrocarbon group optionally including one or more polar moieties selected from a halogen atom, a cyano group, a hydroxyl group, a carboxylate group, a thiol group, O, C═O, C(═O)O, OC(═O), S(═O)O, OS(═O), a lactone moiety, a sultone moiety, and a carboxylic anhydride moiety.

11. The polymer of claim 9,
wherein the third repeating unit and the fourth repeating unit are each independently selected from Group II:

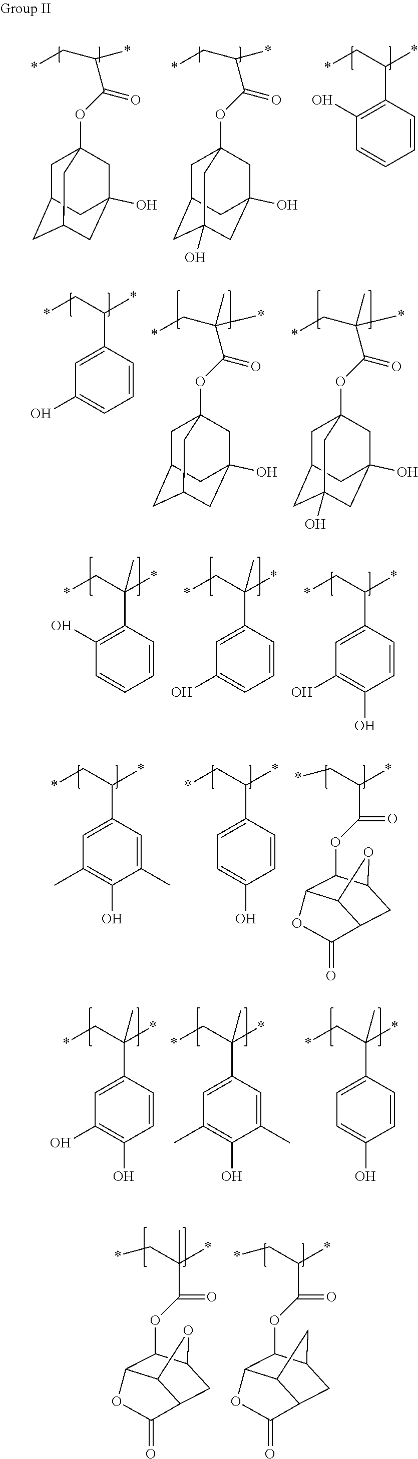

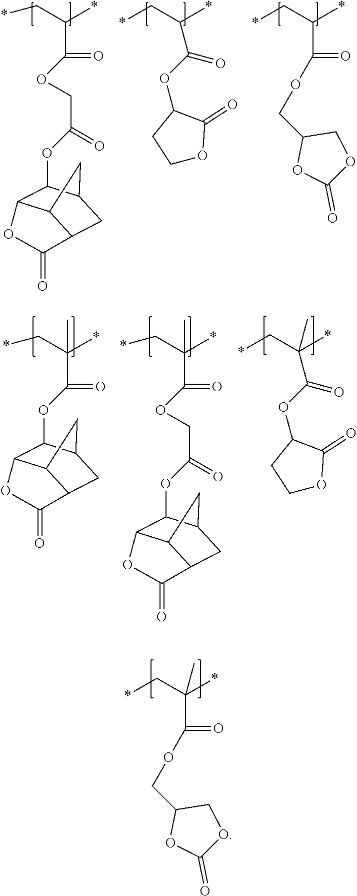

12. The polymer of claim 1,
wherein the polymer comprises a partial structure represented by any one of Formulae 11 to 14: 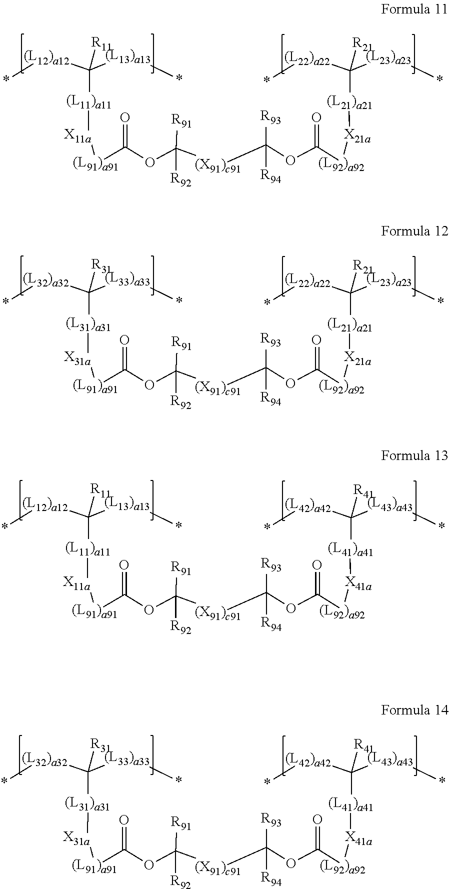
wherein, in Formulae 11 to 14,
L₁₁ to L₁₃ are each independently: a single bond; O; S; C(═O); C(═O)O; OC(═O); C(═O)NR₁₂; NR₁₂C(═O); S(═O); S(═O)₂O; OS(═O)₂; or a linear, branched, or cyclic C₁-C₃₀ divalent hydrocarbon group optionally including a heteroatom,
L₂₁ to L₂₃ are each independently: a single bond; O; S; C(═O); C(═O)O; OC(═O); C(═O)NR₂₂; NR₂₂C(═O); S(═O); S(═O)₂O; OS(═O)₂; or a linear, branched, or cyclic C₁-C₃₀ divalent hydrocarbon group optionally including a heteroatom,
L₃₁ to L₃₃ are each independently: a single bond; O; S; C(═O); C(═O)O; OC(═O); C(═O)NR₃₂; NR₃₂C(═O); S(═O); S(═O)₂O; OS(═O)₂; or a linear, branched, or cyclic C₁-C₃₀ divalent hydrocarbon group optionally including a heteroatom,
L₄₁ to L₄₃ are each independently: a single bond; O; S; C(═O); C(═O)O; OC(═O); C(═O)NR₄₂; NR₄₂C(═O); S(═O); S(═O)₂O; OS(═O)₂; or a linear, branched, or cyclic C₁-C₃₀ divalent hydrocarbon group optionally including a heteroatom,
a11 to a13, a21 to a23, a31 to a33, and a41 to a43 are each independently an integer from 1 to 4,
R₁₁, R₁₂, R₂₁, R₂₂, R₃₁, R₃₂, R₄₁, and R₄₂ are each independently: hydrogen; deuterium; a halogen atom; a cyano group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched, or cyclic C₁-C₃₀ monovalent hydrocarbon group optionally including a heteroatom,
L₉₁ and L₉₂ are each independently: a single bond; or a linear, branched, or cyclic C₁-C₃₀ divalent hydrocarbon group optionally including a heteroatom,
a91 and a92 are each independently an integer from 1 to 4,
R₉₁ to R₉₄ are each independently a linear, branched, or cyclic C₁-C₃₀ monovalent hydrocarbon group optionally including a heteroatom, and R₉₁ and R₉₂ or R₉₃ and R₉₄ are optionally bonded to each other to form a ring,
X₉₁ is a linear, branched, or cyclic C₁-C₃₀ divalent hydrocarbon group optionally including a heteroatom,
c91 is an integer from 1 to 4,
X₁₁a and X₂₁a are each independently a divalent acid labile group,
X₃₁a and X₄₁a are each independently a divalent non-acid labile group, and
* indicates a binding site to a neighboring atom.

13. The polymer of claim 1,
wherein the polymer comprises a partial structure represented by Formula 14-1: 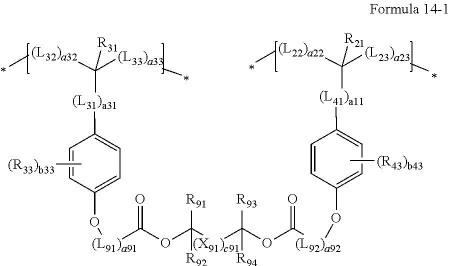
wherein, in Formula 14-1,
L₃₁ to L₃₃ are each independently: a single bond; O; S; C(═O); C(═O)O; OC(═O); C(═O)NR₃₂; NR₃₂C(═O); S(═O); S(═O)₂O; OS(═O)₂; or a linear, branched, or cyclic C₁-C₃₀ divalent hydrocarbon group optionally including a heteroatom,
L₄₁ to L₄₃ are each independently: a single bond; O; S; C(═O); C(═O)O; OC(═O); C(═O)NR₄₂; NR₄₂C(═O); S(═O); S(═O)₂O; OS(═O)₂; or a linear, branched, or cyclic C₁-C₃₀ divalent hydrocarbon group optionally including a heteroatom,
a31 to a33, and a41 to a43 are each independently an integer from 1 to 4,
R₃₁, R₃₂, R₄₁, and R₄₂ are each independently: hydrogen; deuterium; a halogen atom; a cyano group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched, or cyclic C₁-C₃₀ monovalent hydrocarbon group optionally including a heteroatom,
L₉₁ and L₉₂ are each independently: a single bond; or a linear, branched, or cyclic C₁-C₃₀ divalent hydrocarbon group optionally including a heteroatom,
a91 and a92 are each independently an integer from 1 to 4,
R₉₁ to R₉₄ are each independently a linear, branched, or cyclic C₁-C₃₀ monovalent hydrocarbon group optionally including a heteroatom, and R₉₁ and R₉₂ or R₉₃ and R₉₄ are optionally bonded to each other to form a ring,
X₉₁ is a linear, branched, or cyclic C₁-C₃₀ divalent hydrocarbon group optionally including a heteroatom,
c91 is an integer from 1 to 4,
R₃₃ and R₄₃ are each independently hydrogen; deuterium; a halogen atom; a cyano group; a hydroxyl group; an amino group; a carboxylate group; a thiol group; a carbonyl moiety; an ester moiety; a sulfonate moiety; a carbonate moiety; a carbamate moiety; a lactone moiety; a sultone moiety; a carboxylic anhydride moiety; or a linear, branched, or cyclic C₁-C₃₀ monovalent hydrocarbon group optionally including a heteroatom,
b33 and b43 are each independently an integer from 1 to 4, and
* indicates a binding site to a neighboring atom.

14. A resist composition comprising:
the polymer of claim 1;
a photoacid generator; and
a solvent.

15. The resist composition of claim 14,
wherein the photoacid generator is represented by Formula 7:
Formula 7
B₇₁⁺ A₇₁⁻
wherein, in Formula 7,
B₇₁⁺ is represented by Formula 7A, and A₇₁⁻ is represented by any one of Formulae 7B to 7D,
B₇₁⁺ and A₇₁⁻ are optionally linked via a carbon-carbon covalent bond: 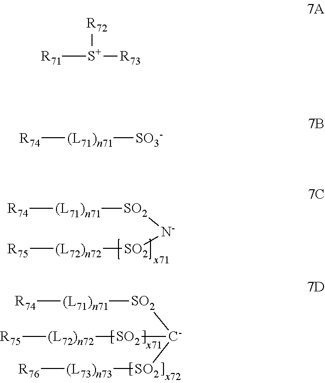
wherein, in Formulae 7A to 7D,
L₇₁ to L₇₃ are each independently a single bond or CRR′,
R and R′ are each independently hydrogen, deuterium, a halogen atom, a cyano group, a hydroxyl group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group,
n71 to n73 are each independently 1, 2, or 3,
x71 and x72 are each independently 0 or 1,
R₇₁ to R₇₃ are each independently a linear, branched, or cyclic C₁-C₃₀ monovalent hydrocarbon group optionally including a heteroatom,
a neighboring two groups among R₇₁ to R₇₃ are optionally bonded to each other to form a condensed ring, and
R₇₄ to R₇₆ are each independently: hydrogen; a halogen atom; or a linear, branched, or cyclic C₁-C₃₀ monovalent hydrocarbon group optionally including a heteroatom.

16. The resist composition of claim 14, further comprising:
a quencher.

17. The resist composition of claim 16,
wherein the quencher is represented by Formula 8,
B₈₁⁺A₈₁⁻ Formula 8
wherein, in Formula 8,
B₈₁⁺ is represented by any one of Formulae 8A to 8C, and
A₈₁⁻ is represented by any one of Formulae 8D to 8F,
B₈₁⁺ and A₈₁⁻ are optionally linked via a carbon-carbon covalent bond, 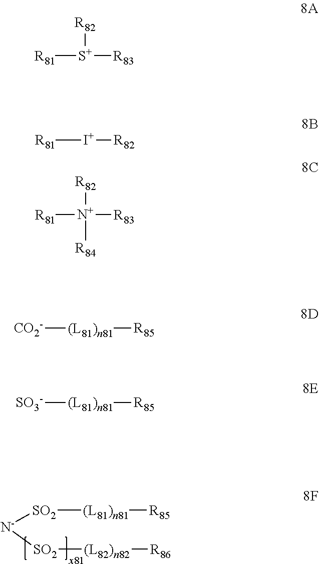
wherein, in Formulae 8A to 8F,
L₈₁ and L₈₂ are each independently a single bond or CRR′,
R and R′ are each independently hydrogen, deuterium, a halogen atom, a cyano group, a hydroxyl group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group,
n81 and n82 are each independently 1, 2, or 3,
x81 is 0 or 1,
R₈₁ to R₈₄ are each independently a linear, branched, or cyclic C₁-C₃₀ monovalent hydrocarbon group optionally including a heteroatom,
a neighboring two groups among R₈₁ to R₈₄ are optionally bonded to each other to form a condensed ring, and
R₈₅ and R₈₆ are: hydrogen; a halogen atom; or a linear, branched, or cyclic C₁-C₃₀ monovalent hydrocarbon group optionally including a heteroatom.

18. A pattern formation method comprising:
applying the resist composition of claim 14 onto a substrate to form a resist film;
exposing at least a portion of the resist film to a high-energy ray to provide an exposed resist film; and
developing the exposed resist film using a developer.

19. The pattern formation method of claim 18,
wherein the exposing is performed by irradiating at least one of an ultraviolet ray, a deep ultraviolet (DUV) ray, an extreme ultraviolet (EUV) ray, an X-ray, a γ-ray, an electron beam (EB), or an α-ray.

20. The pattern formation method of claim 18,
wherein the exposed resist film comprises an exposed portion and an unexposed portion, and
the exposed portion is removed during the developing.
